(19) United States
(12) Patent Application Publication
(10) Pub. No.: US 2025/0359456 A1
(43) Pub. Date: Nov. 20, 2025

(54) DISPLAY DEVICE AND METHOD OF MANUFACTURING THE DISPLAY DEVICE

(71) Applicant: Samsung Display Co., Ltd., Yongin-si (KR)

(72) Inventors: KANG SOO HAN, Yongin-si (KR); KANGUK KIM, Yongin-si (KR); KWANG-MIN LEE, Yongin-si (KR); CHEHO LIM, Yongin-si (KR)

(21) Appl. No.: 19/048,682

(22) Filed: Feb. 7, 2025

(30) Foreign Application Priority Data
May 16, 2024 (KR) 10-2024-0063689

(51) Int. Cl. H10K 59/38; H10K 59/122; H10K 59/80; H10K 59/88; H10K 102/00

(52) U.S. Cl. CPC H10K 59/38; H10K 59/122; H10K 59/873; H10K 59/88; H10K 2102/351

(57) ABSTRACT

A display device and a method for manufacturing the display device are disclosed. The display device may include a display panel including a display area and a peripheral area that is around (or surrounds) the display area and a light control member on the display panel. The light control member may include a light conversion layer, a light transmitting layer spaced and/or apart (e.g., spaced apart or separated) from the light conversion layer, a bank layer including a first bank layer between the light conversion layer and the light transmitting layer and a second bank layer that overlaps the peripheral area, and a plurality of spacers including a first spacer on a lower surface of the first bank layer that is opposite to (or faces) the display panel and a second spacer on a lower surface of the second bank layer that is opposite to (or faces) the display panel.

### CROSS-REFERENCE TO RELATED APPLICATION

The present application claims priority to and the benefit of Korean Patent Application No. 10-2024-0063689, filed on May 16, 2024, in the Korean Intellectual Property Office, the entire disclosure of which is incorporated herein by reference.

### BACKGROUND

### 1. Field

One or more embodiments of the present disclosure relate to a display device, a method of manufacturing the display device, and an electronic device including the display device.

### 2. Description of the Related Art

Multimedia display devices, such as televisions, mobile phones, tablet computers, car navigation units, game machines, and/or similar devices, typically include a display panel to display an image. The display panel may include a plurality of pixels to display an image, and each of the pixels may include a light emitting element that produces or generates light and a driving element connected to the light emitting element.

To improve or enhance the visibility and color purity of display devices, a display device incorporating a light conversion layer is being developed. This device is manufactured by bonding a substrate with light-emitting elements to a substrate with the light conversion layer. However, defects may arise during the bonding process, necessitating further research to address this issue.

### SUMMARY

One or more aspects of embodiments of the present disclosure are directed toward a display device with (having) reduced defects (e.g., a degree or occurrence of defects, for example, made in the process of bonding the substrates of the display device) at (in) the border of the display device, a method of manufacturing the display device, and an electronic device including the display device. For example, a display device is designed to minimize or reduce defects (e.g., the degree or occurrence of defects, particularly those arising during the substrate bonding process) at the borders of the display device.

Additional aspects of embodiments will be set forth in part in the description which follows and, in part, will be apparent from the description or may be learned by practice of the presented embodiments of the disclosure.

One or more embodiments of the present disclosure provide a display device that includes a display panel including a display area and a peripheral area that is around (e.g., surrounds) the display area and a light control member arranged or provided on the display panel. The light control member includes a light conversion layer that overlaps the display area, a light transmitting layer that overlaps the display area and that is spaced and/or apart (e.g., spaced apart or separated) from the light conversion layer, a bank layer including a first bank layer arranged or provided between the light conversion layer and the light transmitting layer and a second bank layer that overlaps the peripheral area, and a plurality of spacers including a first spacer arranged or provided on a lower surface of the first bank layer that is opposite to (or faces) the display panel and a second spacer arranged or provided on a lower surface of the second bank layer that is opposite to (or faces) the display panel, and the first spacer and the second spacer have different thicknesses.

One or more embodiments of the present disclosure provide a display device that includes a display panel including a display area and a peripheral area that is around (e.g., surrounds) the display area in a plan view (e.g., when viewed from above a plane) and a light control member arranged or provided on the display panel. The light control member includes an upper substrate, a bank layer that is arranged or provided between the upper substrate and the display panel and that defines a first opening, a second opening, a third opening, and a plurality of dummy openings spaced and/or apart (e.g., spaced apart or separated) from one another, a light transmitting layer arranged or provided in the first opening, light conversion layers arranged or provided in the second opening and the third opening, and a plurality of spacers including a first spacer that is arranged or provided in the plurality of dummy openings and that overlaps the display area and a second spacer that is arranged or provided in the plurality of dummy openings and that overlaps the peripheral area, and the first spacer has a greater thickness than the second spacer.

One or more embodiments of the present disclosure provide a method for manufacturing a display device that includes a step (e.g., act or task) of providing (e.g., forming or applying) a bank layer by performing an exposure process on a preliminary bank layer on an upper substrate, a step of providing a light transmitting layer by discharging an ink (e.g., a first ink) into a first opening defined by the bank layer, a step (e.g., act or task) of providing a spacer by discharging an ink (e.g., a second ink) onto the bank layer, and a step (e.g., act or task) of bonding a display panel and the upper substrate to each other by placing the upper substrate on the display panel including a display area and a peripheral area adjacent to the display area. The light transmitting layer and the spacer are concurrently (e.g., simultaneously) provided. The spacer includes a first spacer that overlaps the display area and a second spacer that overlaps the peripheral area. The first spacer has a greater thickness than the second spacer.

In one or more embodiments, the ink may include a first ink and a second ink. The first ink and the second ink may be substantially the same. The first ink and the second ink may be substantially different. The first ink may be discharged into a first opening defined by the bank layer to provide a light transmitting layer. The second ink may be discharged onto a bank layer to provide a spacer.

One or more embodiments of the present disclosure provide an electronic device that includes a power supply module configured or provided to supply power and the display device as described in one or more embodiments, wherein the display device is connected to the power supply module.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The above and other aspects and features of certain embodiments of the present disclosure will become more apparent from the following description taken in conjunction with the accompanying drawings.

FIG. 1 is a perspective view of a display device according to one or more embodiments of the present disclosure.

FIG. 2 is an exploded perspective view of the display device illustrated in FIG. 1.

FIG. 3 is a sectional view (e.g., cross-sectional view) of a display module according to one or more embodiments.

FIG. 4 is a plan view of a display panel illustrated in FIG. 2.

FIG. 5 is an enlarged plan view of the display panel illustrated in FIG. 4.

FIG. 6 is a sectional view (e.g., cross-sectional view) of the display panel according to one or more embodiments of the present disclosure.

FIG. 7 is a sectional view (e.g., cross-sectional view) of a portion of the display module that corresponds to the line II-II′ illustrated in FIG. 5.

FIG. 8 is a sectional view (e.g., cross-sectional view) taken along the line I-I′ illustrated in FIG. 2.

FIG. 9 is a sectional view (e.g., cross-sectional view) of the display module according to one or more embodiments of the present disclosure.

FIG. 10A is a plan view of a light control member according to one or more embodiments of the present disclosure.

FIG. 10B is a sectional view (e.g., cross-sectional view) of a portion that corresponds to the line III-III′ illustrated in FIG. 10A.

FIG. 10C is a view to illustrate a peripheral area of the display device including a bank layer illustrated in FIG. 10A.

FIG. 11A is a sectional view (e.g., cross-sectional view) of the display module according to one or more embodiments of the present disclosure.

FIG. 11B is a sectional view (e.g., cross-sectional view) of the display module according to one or more embodiments of the present disclosure.

FIGS. 12A-12D are views to illustrate a method of manufacturing the light control member illustrated in FIG. 8.

FIGS. 13A and 13B are views to illustrate a method of manufacturing the light control member illustrated in FIG. 11B.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout, and duplicative descriptions thereof may not be provided in the specification.

In one or more embodiments, if (e.g., when) a component (e.g., an area, a layer, a part, and/or the like) is referred to as being “on”, “connected to”, or “coupled to” another component, this refers to that the component may be directly on, directly connected to, or directly coupled to the other component or a third component may be present therebetween. In contrast, if (e.g., when) a component is referred to as being “directly on”, “directly connected to”, or “directly coupled to” another component, there may be no intervening components present.

Identical reference numerals refer to substantially identical components. Additionally, in the drawings, the thicknesses, proportions, and dimensions of components may be exaggerated for effective description. As used herein, the term “and/or” includes all of one or more combinations defined by related components.

Terms, such as “first”, “second”, and/or the like, may be used to describe one or more suitable components, but the components should not be limited by the terms. The terms may be used only to distinguish one component from other components. For example, without departing the scope of the present disclosure, a first component may be referred to as a second component, and similarly, the second component may also be referred to as the first component. The terms of a singular form may include plural forms unless otherwise specified.

In one or more embodiments, terms, such as “below”, “under”, “above”, and “over”, are used to describe a relationship between components illustrated in the drawings. The terms are relative concepts and are described based on directions illustrated in the drawing.

It should be understood that terms, such as “include”, “including”, “have”, and “having”, if (e.g., when) used herein, specify the presence of stated features, numbers, steps (e.g., acts or tasks), operations, components, parts, and/or one or more (e.g., any suitable) combinations thereof, but do not preclude the presence or addition of one or more other features, numbers, steps (e.g., acts or tasks), operations, components, parts, and/or one or more (e.g., any suitable) combinations thereof.

Unless otherwise defined, all terms used herein, including technical or scientific terms, have substantially the same meanings as those generally understood by those skilled in the art to which the present disclosure pertains. Such terms as those defined in a generally used dictionary are to be interpreted as having meanings substantially equal to the contextual meanings in the relevant field of art, and are not to be interpreted as having ideal or excessively (or substantially) formal meanings unless clearly defined as having such in the present disclosure.

Hereinafter, embodiments of the present disclosure will be described with reference to the accompanying drawings.

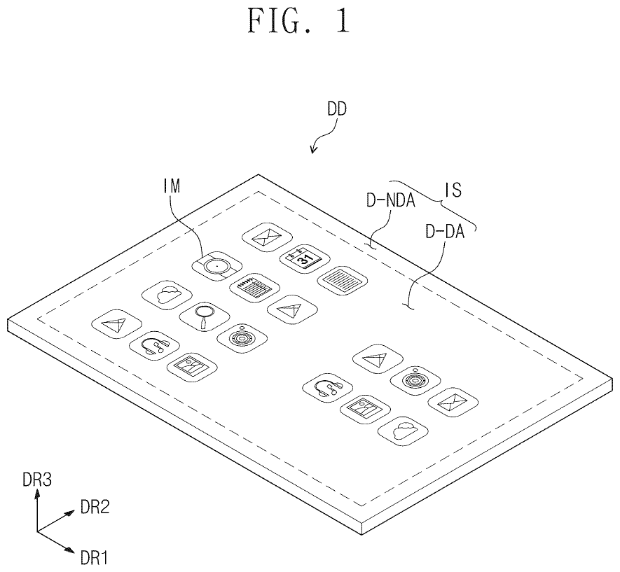

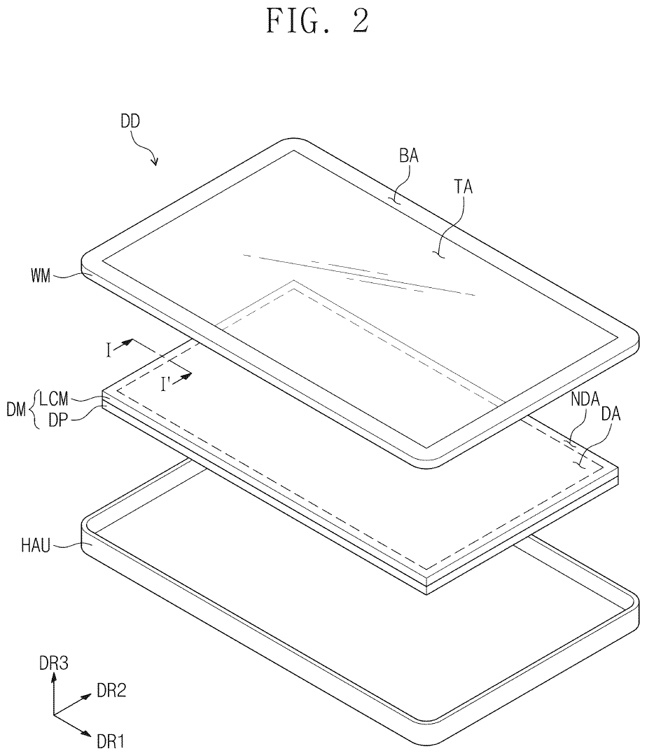

FIG. 1 is a perspective view of a display device according to one or more embodiments of the present disclosure. FIG. 2 is an exploded perspective view of the display device illustrated in FIG. 1.

Referring to FIG. 1, the display device DD, in a plan view (e.g., when viewed from above a plane), may have a rectangular (e.g., substantially rectangular) shape having long sides that extends in a first direction DR1 and short sides that extends in a second direction DR2 that crosses the first direction DR1. However, without being limited thereto, the display device DD may have one or more suitable shapes, such as a circular (e.g., substantially circular) shape, a polygonal (e.g., substantially polygonal) shape, and/or the like.

Hereinafter, a direction that is substantially normal (e.g., perpendicular) to a plane defined by the first direction DR1 and the second direction DR2 may be defined as a third direction DR3. The expression “when viewed from above the plane” or “in a plan view” used herein may refer to that it is viewed in the third direction DR3. The expression “on a section” or “in a cross-sectional view” used herein may refer to that it is viewed in the first direction DR1 or the second direction DR2.

In the present context and unless defined otherwise, “a plan view” refers to a view from above, looking down on the object as if it were laid out flat, for example, in the third direction DR3, which is perpendicular or normal to the plane defined by DR1 and DR2.

In the present context and unless defined otherwise, “a cross-sectional view” refers to a view that looks at the object as if it were cut along a plane (e.g., slice through an object using an imaginary flat surface (the plane) that divides the object into two parts), for example, in the first direction DR1 or the second direction DR2. This indicates that the cross-sectional view shows the internal structure of the object as if it were cut along a plane parallel to either DR1 or DR2.

The display device DD may be to display an image IM in the third direction DR3 through a display surface IS that is substantially parallel to the plane defined by the first direction DR1 and the second direction DR2. The third direction DR3 may be substantially parallel to the normal direction of the display surface IS. The display surface IS on which the image IM is displayed may correspond to the front surface of the display device DD. The image IM may include a still image as well as a dynamic image. In FIG. 1, icon images are illustrated as an example of the image IM.

In one or more embodiments, front surfaces (or upper surfaces) and rear surfaces (or lower surfaces) of members or units may be defined based on the direction in which the image IM is displayed. The front surfaces and the rear surfaces may be opposite to (or face) each other in the third direction DR3, and the normal directions of the front surfaces and the rear surfaces may be substantially parallel to the third direction DR3. The separation distances between the front surfaces and the rear surfaces that are defined in the third direction DR3 may correspond to the thicknesses of the members (or the units).

FIG. 1 illustrates the display device DD having the flat (e.g., substantially flat) display surface IS. However, the display surface IS of the display device DD is not limited thereto and may have a curved shape or a three-dimensional shape.

The display device DD may be a flexible (e.g., substantially flexible) display device. The term “flexible” used herein may refer to a property of being bent and may include everything from a structure that is able to be fully folded to a structure that is able to be bent to a level of several nanometers. For example, the display device DD that is flexible may be a curved (e.g., substantially curved) display device or a foldable (e.g., substantially foldable) display device. Without being limited thereto, the display device DD may be a rigid (e.g., substantially rigid) display device.

The display surface IS of the display device DD may include a display part D-DA and a non-display part D-NDA. The display part D-DA may be a part where the image IM is displayed on the front surface of the display device DD, and a user may visually recognize the image IM through the display part D-DA. Although the display part D-DA having a rectangular (e.g., substantially rectangular) shape is illustrated in one or more embodiments, the display part D-DA may have one or more suitable shapes depending on the desired design.

The non-display part D-NDA may be a part where the image IM is not displayed on the front surface of the display device DD. The non-display part D-NDA may have a set or predetermined color and may block light. The non-display part D-NDA may be adjacent to the display part D-DA. For example, the non-display part D-NDA may be arranged or provided outside the display part D-DA and may be around (e.g., surround) the display part D-DA. However, this is illustrative, and the non-display part D-NDA may be adjacent to only one side of the display part D-DA, or may be arranged or provided on the side surface rather than the front surface of the display device DD. Without being limited thereto, the non-display part D-NDA may not be provided.

The display device DD according to one or more embodiments may be to sense an external input applied from the outside. The external input may have one or more suitable forms, such as pressure, temperature, light, and/or the like, that are provided from the outside. The external input may include not only an input making contact with the display device DD (e.g., contact by a hand of the user or a pen) but also an input (e.g., hovering) applied in proximity to the display device DD.

Referring to FIG. 2, the display device DD may include a window WM, a display module DM, and an outer case HAU. The display module DM may include a display panel DP and a light control member LCM arranged or provided on the display panel DP.

The window WM and the outer case HAU may be combined to provide the exterior of the display device DD and may provide an inner space in which components of the display device DD, such as the display module DM, are accommodated or provided.

The window WM may be arranged or provided on the display module DM. The window WM may be to protect the display module DM from external impact. The front surface of the window WM may correspond to the display surface IS of the display device DD as described in one or more embodiments. The front surface of the window WM may include a transmissive area TA and a bezel area BA.

The transmissive area TA of the window WM may be an optically clear (e.g., substantially clear) area. The window WM may be to transmit, through the transmissive area TA, an image provided by the display module DM, and the user may visually recognize the corresponding image. The transmissive area TA may correspond to the display part D-DA (refer to FIG. 1) of the display device DD. In one or more embodiments, the expression “one area/portion corresponds to another area/portion” used herein refers to that “the areas/portions overlap each other,” but is not limited to having substantially the same area and/or shape.

The window WM may include an optically clear (e.g., substantially clear) insulating (e.g., electrically insulating) material (e.g., an electron insulator). For example, the window WM may include glass, sapphire, and/or plastic. The window WM may have a single-layer structure or a multi-layer structure. The window WM may further include functional layers, such as an anti-fingerprint layer, a phase control layer, and/or a hard coating layer, which are arranged or provided on an optically clear (e.g., substantially clear) substrate.

The bezel area BA of the window WM may be an area where a material having a set or predetermined color is deposited, coated, or printed on the optically clear (e.g., substantially clear) substrate. The bezel area BA of the window WM may be to prevent a component of the display module DM arranged or provided to overlap the bezel area BA from being visible from the outside (or reduce a degree or occurrence of being visible from the outside). The bezel area BA may correspond to the non-display part D-NDA (refer to FIG. 1) of the display device DD.

The display module DM may be arranged or provided between the window WM and the outer case HAU. The display module DM may be to display an image in response to an electrical signal. The display module DM may include a display area DA and a peripheral area NDA adjacent to the display area DA.

The display area DA may be an area activated depending on an electrical signal. The display area DA may be an area that outputs an image provided from the display module DM. The display area DA of the display module DM may correspond to the transmissive area TA as described in one or more embodiments. An image generated in the display area DA may be visible from the outside through the transmissive area TA.

The peripheral area NDA may be adjacent to the display area DA. For example, the peripheral area NDA may be around (e.g., surround) the display area DA. However, without being limited thereto, the peripheral area NDA may be defined in one or more suitable shapes. The peripheral area NDA may be an area where a driving circuit or driving wiring for driving elements arranged or provided in the display area DA, one or more suitable types or kinds of signal lines that provide electrical signals, and pads are arranged or provided. The peripheral area NDA of the display module DM may correspond to the bezel area BA of the window WM, and the bezel area BA may be to prevent components of the display module DM arranged or provided in the peripheral area NDA from being visible from the outside (or reduce a degree or occurrence of being visible from the outside).

The display panel DP according to one or more embodiments may be an emissive display panel and is not particularly limited thereto. For example, the display panel DP may be an organic light emitting display panel, an inorganic light emitting display panel, or a quantum-dot light emitting display panel. An emissive layer of the organic light emitting display panel may include an organic luminescent material, and an emissive layer of the inorganic light emitting display panel may include an inorganic luminescent material. An emissive layer of the quantum-dot light emitting display panel may include quantum dots and/or quantum rods. Hereinafter, it will be exemplified that the display panel DP is an organic light emitting display panel.

The light control member LCM may be to convert the wavelength of light provided from the display panel DP or may be to selectively transmit light provided from the display panel DP. In one or more embodiments, the light control member LCM may be to prevent the reflection of external light incident from outside the display device DD (or reduce a degree or occurrence of the reflection of external light incident from outside the display device DD).

The outer case HAU may be arranged or provided under the display module DM and may accommodate or provide the display module DM. The outer case HAU may be to protect the display module DM by absorbing impact applied to the display module DM from the outside and preventing infiltration (or reducing a degree or occurrence of infiltration) of foreign matter (or undesirable impurities) and/or moisture into the display module DM. The outer case HAU according to one or more embodiments may be implemented in a form in which a plurality of receiving members are combined.

In one or more embodiments, the display device DD may further include an input sensing module. The input sensing module may be to obtain information about the coordinates of an external input applied from outside the display device DD. The input sensing module of the display device DD may be driven in one or more suitable ways, such as a capacitance sensing method, a resistance sensing method, an infrared sensing method, or a pressure sensing method, but embodiments of the present disclosure are not limited thereto.

In one or more embodiments, the input sensing module may be arranged or provided on the display module DM. The input sensing module may be directly arranged or provided on the display module DM through a substantially continuous process. However, without being limited thereto, the input sensing module may be manufactured separately from the display module DM and may be attached to the display module DM by an adhesive layer. In one or more embodiments, the input sensing module may be arranged or provided between components of the display module DM. For example, the input sensing module may be arranged or provided between the display panel DP and the light control member LCM.

The display device DD may further include an electronic module including one or more suitable functional modules to operate the display module DM, a power supply module that supplies power desired or required for the display device DD, and a bracket combined with the display module DM and/or the outer case HAU to divide the inner space of the display device DD.

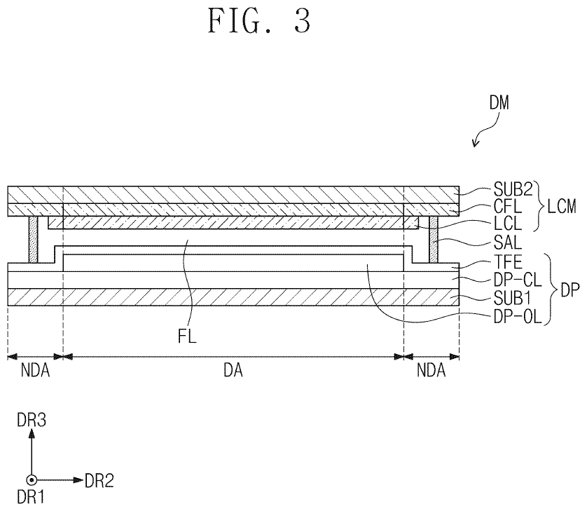

FIG. 3 is a sectional view of the display module according to one or more embodiments.

Referring to FIG. 3, the display module DM may include the display panel DP, the light control member LCM, a filling member FL, and a plurality of sealing members SAL. The foregoing description may be substantially identically applied to the display panel DP (or the first substrate) and the light control member LCM (or the second substrate).

The display panel DP may further include a first base substrate SUB1 (or a lower substrate), a circuit layer DP-CL, a light emitting element layer DP-OL, and an encapsulation layer TFE.

The first base substrate SUB1 may include a glass substrate, a polymer substrate, or an organic/inorganic composite substrate. The first base substrate SUB1 may include upper and lower surfaces that are substantially parallel to the first direction DR1 and the second direction DR2. The circuit layer DP-CL, the light emitting element layer DP-OL, and the encapsulation layer TFE may be sequentially stacked on the upper surface of the first base substrate SUB1, and this may be defined as the first substrate.

The light emitting element layer DP-OL may include light emitting elements arranged or provided to overlap the display area DA. The circuit layer DP-CL may be arranged or provided between the light emitting element layer DP-OL and the first base substrate SUB1 and may include driving elements, signal lines, and signal pads that are connected to the light emitting elements. The light emitting elements of the light emitting element layer DP-OL may provide source light (or first light) toward the light control member LCM in the display area DA.

The encapsulation layer TFE may be arranged or provided on the light emitting element layer DP-OL and may seal the light emitting elements. The encapsulation layer TFE may include a plurality of thin films. The thin films of the encapsulation layer TFE may improve or enhance the optical efficiency of the light emitting elements or may protect the light emitting elements (e.g., protect the light emitting elements from foreign matter (or undesirable impurities) and/or moisture from outside and/or external force).

The light control member LCM may include a second base substrate SUB2 (or an upper substrate), a color filter layer CFL, and a light control layer LCL. The second base substrate SUB2 may include a front surface and a rear surface that are substantially parallel to the first direction DR1 and the second direction DR2. The rear surface of the second base substrate SUB2 may be opposite to (or face) the upper surface of the first base substrate SUB1. The color filter layer CFL and the light control layer LCL may be sequentially stacked on the rear surface of the second base substrate SUB2, and this may be defined as the second substrate.

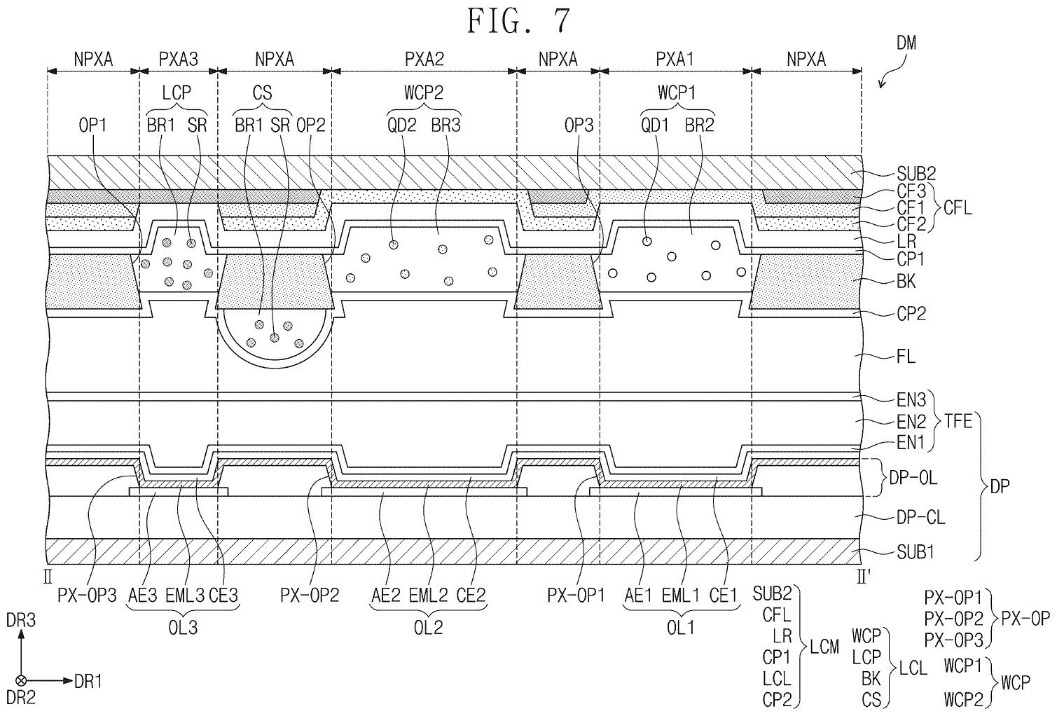

The light control layer LCL may be arranged or provided to overlap the display area DA and may include a light transmitting layer LCP (refer to FIG. 7) and light conversion layers WCP (refer to FIG. 7) that are to convert the optical property of the source light provided by the light emitting elements. The light control layer LCL may be to selectively convert or transmit the color of the source light. A portion of the light control layer LCL may overlap the peripheral area NDA.

The color filter layer CFL may be arranged or provided to overlap the display area DA and may be to transmit light selectively converted or transmitted by the light control layer LCL. The color filter layer CFL may be to absorb light that is not converted by the light control layer LCL and that passes through the light control layer LCL, thereby preventing degradation (or reduce a degree or occurrence of degradation) in the color purity of the display device DD (refer to FIG. 1). The color filter layer CFL may include color filters CF1, CF2, and CF3 (refer to FIG. 7) that are to display substantially the same colors as pixels. In one or more embodiments, the color filter layer CFL may be to filter external light into substantially the same colors as the pixels, and the reflectance (or a degree or occurrence of the reflectance) of the external light may be reduced.

A portion of the color filter layer CFL may be arranged or provided to overlap the peripheral area NDA. The color filter layer CFL may include color filter layers CFL sequentially stacked in the peripheral area NDA and may be to absorb light emitted or reflected through the peripheral area NDA.

The sealing members SAL may be arranged or provided between the display panel DP and the light control member LCM and may bond the display panel DP and the light control member LCM to each other. The sealing members SAL may be arranged or provided to overlap the peripheral area NDA.

For example, through separate processes, the components of the display panel DP may be provided on the first base substrate SUB1, and the light control layer LCL and the color filter layer CFL may be provided on the second base substrate SUB2. Thereafter, the display panel DP and the light control member LCM may be bonded to each other by the sealing members SAL and may be provided as the display module DM. The sealing members SAL may include a UV curable material.

Although it has been described that the sealing members SAL are attached to the lower surface of the color filter layer CFL that is opposite to (or faces) the display panel DP, embodiments of the present disclosure are not limited thereto, and the sealing members SAL may be attached to the border of the light control layer LCL.

The filling member FL may be arranged or provided between the display panel DP and the light control member LCM and may fill the empty space between the display panel DP and the light control member LCM that overlaps the display area DA. In one or more embodiments, the filling member FL may be arranged or provided between the encapsulation layer TFE of the display panel DP and the light control layer LCL. The filling member FL may include silicone, epoxy, and/or an acrylic thermosetting material. However, the material of the filling member FL is not limited thereto.

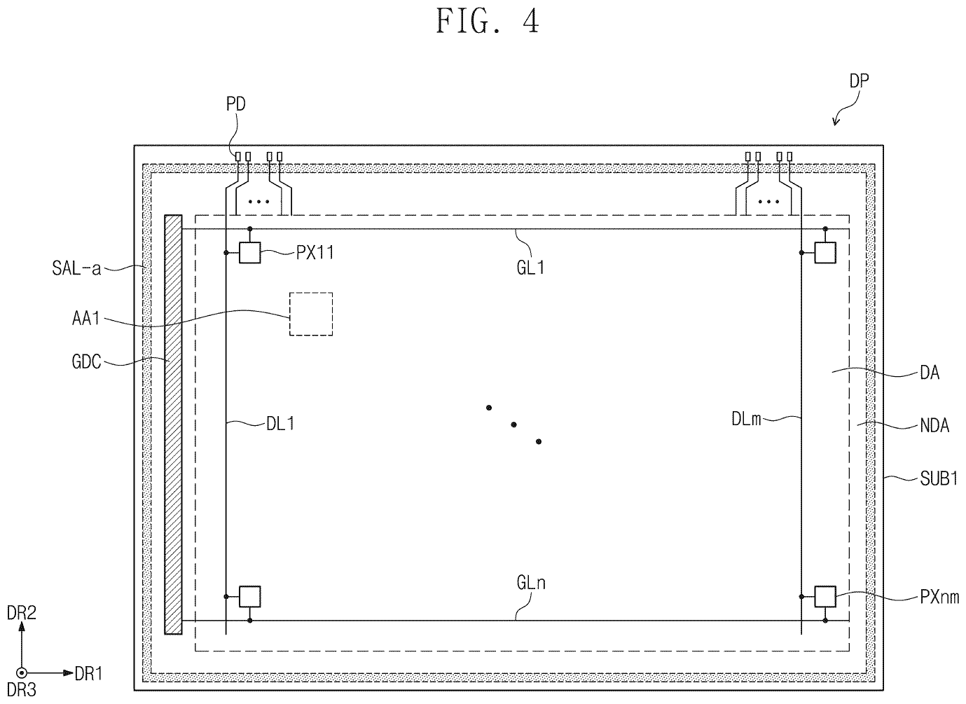

FIG. 4 is a plan view of the display panel illustrated in FIG. 2.

Referring to FIG. 4, the first base substrate SUB1 of the display panel DP may include a display area DA and a peripheral area NDA. The display panel DP may include pixels PX11 to PXnm arranged or provided in the display area DA and signal lines GL1 to GLn and DL1 to DLm electrically connected to the pixels PX11 to PXnm. The display panel DP may include a driving circuit GDC and pads PD arranged or provided in the peripheral area NDA.

Each of the pixels PX11 to PXnm may include a light emitting element that will be described in more detail and a pixel driving circuit that includes a plurality of transistors (e.g., a switching transistor and a driving transistor) and at least one capacitor that are connected to the light emitting element. The pixels PX11 to PXnm may be to emit light in response to electrical signals applied to the pixels PX11 to PXnm. Although FIG. 4 illustrates the pixels PX11 to PXnm arranged or provided in a matrix form, the arrangement of the pixels PX11 to PXnm is not limited thereto.

The signal lines GL1 to GLn and DL1 to DLm may include gate lines GL1 to GLn and data lines DL1 to DLm. Each of the pixels PX11 to PXnm may be connected to a corresponding gate line among the gate lines GL1 to GLn and a corresponding data line among the data lines DL1 to DLm. The display panel DP may include more types or kinds of signal lines depending on the configurations or arrangements of the pixel driving circuits of the pixels PX11 to PXnm.

The driving circuit GDC may include a gate drive circuit. The gate drive circuit may generate gate signals and may sequentially output the gate signals to the gate lines GL1 to GLn. The gate drive circuit may additionally output other control signals to the pixel driving circuits of the pixels PX11 to PXnm.

The pads PD may be arranged or provided in one direction on the peripheral area NDA. The pads PD may be parts connected to a circuit board. Each of the pads PD may be connected with a corresponding signal line among the plurality of signal lines GL1 to GLn and DL1 to DLm and may be connected to a corresponding pixel through the signal line. The pads PD may have a one-body shape with the signal lines GL1 to GLn and DL1 to DLm. However, without being limited thereto, the pads PD may be arranged or provided on a layer substantially different from the layer on which the signal lines GL1 to GLn and DL1 to DLm are arranged or provided and may be connected with the signal lines GL1 to GLn and DL1 to DLm through contact holes.

FIG. 4 illustrates a sealing member arrangement area SAL-a that corresponds to the area where the sealing members SAL (refer to FIG. 3) are arranged or provided. The sealing member arrangement area SAL-a may overlap the peripheral area NDA and may correspond to a portion of the peripheral area NDA. The sealing member arrangement area SAL-a may be adjacent to the border of the display panel DP and may extend in the extension direction of the border of the display panel DP. The sealing member arrangement area SAL-a may be around (e.g., surround) the display area DA in a plan view (when viewed from above a plane). In one or more embodiments, the sealing member arrangement area SAL-a may be defined outward of the driving circuit GDC.

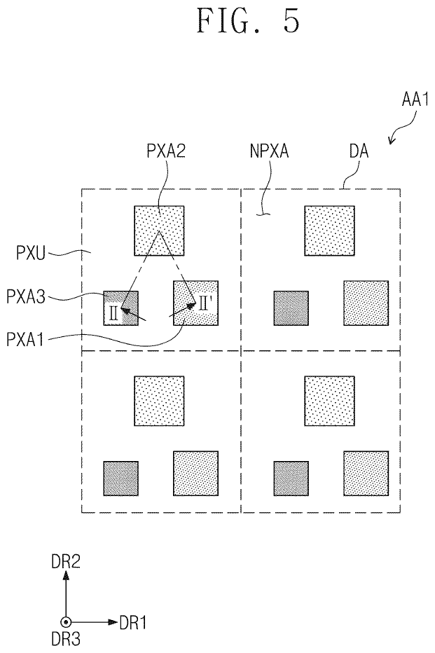

FIG. 5 is an enlarged plan view of the display panel illustrated in FIG. 4.

FIG. 5 is an enlarged plan view of a first area AA1 illustrated in FIG. 4.

Referring to FIG. 5, the display area DA may include a plurality of unit pixels PXU. The unit pixels PXU may be arranged or provided in the first direction DR1 and the second direction DR2. Although four unit pixels PXU are illustrated in FIG. 5, the number of unit pixels PXU is not limited thereto. Hereinafter, one unit pixel PXU among the plurality of unit pixels PXU will be described in more detail.

The unit pixel PXU may include emissive areas PXA1, PXA2, and PXA3 that correspond to light emitting elements and a non-emissive area NPXA around (e.g., surrounding) the emissive areas PXA1, PXA2, and PXA3. In FIG. 5, examples of the shapes of the emissive areas PXA1, PXA2, and PXA3 are illustrated.

The emissive areas PXA1, PXA2, and PXA3 may correspond to areas through which light provided from the light emitting elements is emitted. The emissive areas PXA1, PXA2, and PXA3 may include a first emissive area PXA1, a second emissive area PXA2, and a third emissive area PXA3. The first emissive area PXA1, the second emissive area PXA2, and the third emissive area PXA3 may be distinguished from one another depending on the colors of light emitted toward the outside of the display device DD (refer to FIG. 1). The non-emissive area NPXA may set the boundaries between the emissive areas (e.g., between the first emissive area PXA1 and the second emissive area PXA2, between the first emissive area PXA1 and the third emissive area PXA3, and between the second emissive area PXA2 and the third emissive area PXA3) and may prevent color mixing (or reduce a degree or occurrence of color mixing) between the emissive areas (e.g., between the first emissive area PXA1 and the second emissive area PXA2, between the first emissive area PXA1 and the third emissive area PXA3, and between the second emissive area PXA2 and the third emissive area PXA3). In one or more embodiments, the emissive areas PXA1, PXA2, and PXA3 may correspond to regions where light from the light-emitting elements is emitted. These areas may include a first emissive area PXA1, a second emissive area PXA2, and a third emissive area PXA3, each distinguished by the color of light they emit (refer to FIG. 1). The non-emissive area NPXA sets boundaries between the emissive areas (e.g., between PXA1 and PXA2, PXA1 and PXA3, and PXA2 and PXA3) to prevent or reduce color mixing. For example, the non-emissive area NPXA helps maintain color purity by separating the red light emitted from PXA1, the green light from PXA2, and the blue light from PXA3, ensuring that the colors do not blend together.

One of the emissive areas (e.g., the first emissive area PXA1, the second emissive area PXA2, and the third emissive area PXA3) may provide light of a first color that corresponds to source light provided by a light emitting element, another one may provide light of a second color that is substantially different from the light of the first color, and the other one may provide light of a third color that is substantially different from the light of the first color and the light of the second color. For example, the light of the first color may be blue light, the light of the second color may be red light, and the light of the third color may be green light. However, examples of the light of the first color, the second color, and the third color are not necessarily limited thereto.

In one or more embodiments, the first emissive area PXA1, the second emissive area PXA2, and the third emissive area PXA3 may have substantially the same shape and substantially different planar areas in a plan view (e.g., when viewed from above the plane). For example, the first emissive area PXA1, the second emissive area PXA2, and the third emissive area PXA3 may have substantially the same shape but substantially different planar areas when viewed in a plan view.

The second emissive areas PXA2 arranged or provided in the first direction DR1 may be defined as a first row, and the first emissive areas PXA1 and the third emissive areas PXA3 arranged or provided in the first direction DR1 may be defined as a second row. In the second row, the first emissive areas PXA1 and the third emissive areas PXA3 may alternate with one another in the first direction DR1.

A plurality of first rows, each of which includes the second emissive areas PXA2, may be arranged or provided in the second direction DR2, and similarly, a plurality of second rows may be arranged or provided in the second direction DR2. As illustrated in FIG. 5, the first rows and the second rows may alternate with one another in the second direction DR2.

Each of the first emissive area PXA1, the second emissive area PXA2, and the third emissive area PXA3 may have a quadrangular (e.g., substantially quadrangular) shape, and the first emissive area PXA1, the second emissive area PXA2, and the third emissive area PXA3 may have substantially different planar areas. Although FIG. 5 illustrates an example that the first emissive area PXA1, the second emissive area PXA2, and the third emissive area PXA3 have right-angled corners, embodiments of the present disclosure are not limited thereto, and the first emissive area PXA1, the second emissive area PXA2, and the third emissive area PXA3 may have substantially rounded corners.

For example, in a plan view (when viewed from above a plane), the second emissive areas PXA2 may have a larger area than the first emissive areas PXA1 and the third emissive areas PXA3. If (e.g., when) viewed from above the plane, the first emissive areas PXA1 may have a larger area than the third emissive areas PXA3. For example, the second emissive areas PXA2 may have the largest area, and the third emissive areas PXA3 may have the smallest area.

In one or more embodiments, the arrangement of the first emissive area PXA1, the second emissive area PXA2, and the third emissive area PXA3 illustrated in FIG. 5 is illustrative. Without being limited thereto, the arrangement of the first emissive area PXA1, the second emissive area PXA2, and the third emissive area PXA3 may vary depending on the design of the display device DD (refer to FIG. 1). The shapes, areas, and arrangement of the emissive areas may be designed in one or more suitable ways depending on the light emission efficiency of light depending on colors and are not limited to one or more embodiments illustrated in FIG. 5.

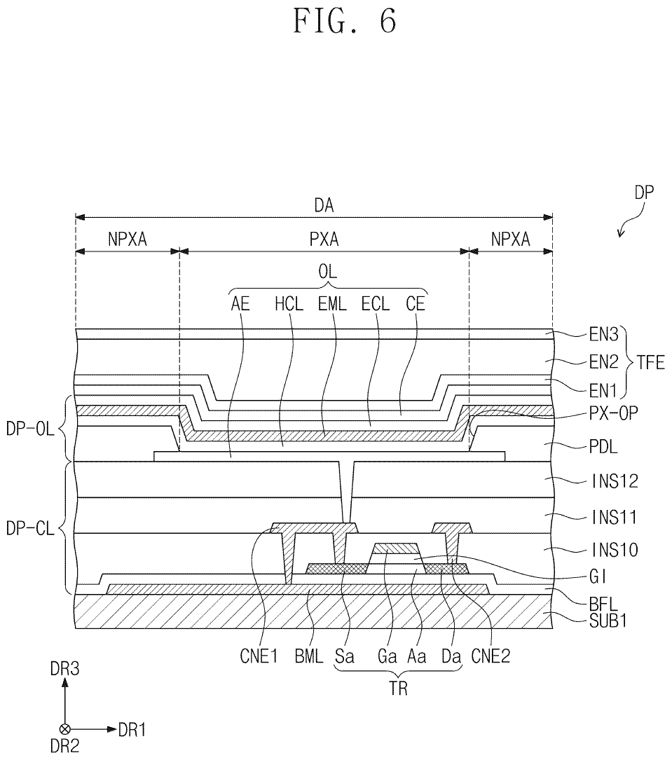

FIG. 6 is a sectional view (e.g., cross-sectional view) of the display panel according to one or more embodiments of the present disclosure.

Referring to FIG. 6, the display panel DP may include the first base substrate SUB1, the circuit layer DP-CL, the light emitting element layer DP-OL, and the encapsulation layer TFE, and the foregoing description may be substantially identically applied to the components.

For example, an emissive area PXA illustrated in FIG. 6 may be one of the first emissive area PXA1, the second emissive area PXA2, and the third emissive area PXA3 illustrated in FIG. 5.

The display panel DP may include insulating (e.g., electrically insulating) layers, a semiconductor pattern, a conductive (e.g., electrically conductive) pattern, and a signal line. In a step (e.g., act or task) of manufacturing the display panel DP, an insulating (e.g., electrically insulating) layer, a semiconductor layer, and a conductive (e.g., electrically conductive) layer may be provided on the first base substrate SUB1 through a process, such as coating, deposition, and/or the like. Thereafter, the insulating (e.g., electrically insulating) layer, the semiconductor layer, and the conductive (e.g., electrically conductive) layer may be selectively subjected to patterning by photolithography. The semiconductor pattern, the conductive (e.g., electrically conductive) pattern, the signal line, and/or the like included in the display panel DP may be provided through the processes as described in one or more embodiments.

Each of the pixels may have an equivalent circuit including transistors, at least one capacitor, and a light emitting element, and the equivalent circuit of the pixel may be modified in one or more suitable forms. The semiconductor pattern may be arranged or provided across the pixels according to a set or predetermined rule depending on the equivalent circuit. In FIG. 6, one transistor TR and one light emitting element OL included in the pixel are illustrated as an example.

The first base substrate SUB1 may provide a base surface on which the circuit layer DP-CL is to be provided. The first base substrate SUB1 may have a single-layer structure or a multi-layer structure. For example, the first base substrate SUB1 having a multi-layer structure may include synthetic resin layers and at least one inorganic layer arranged or provided between the synthetic resin layers or may include a glass substrate and a synthetic resin layer arranged or provided on the glass substrate.

The synthetic resin layer(s) included in the first base substrate SUB1 may include at least one selected from among an acrylic resin, a methacrylic resin, a polyisoprene resin, a vinyl resin, an epoxy resin, a urethane-based resin, a celluosic resin, a siloxane-based resin, a polyamide resin, a perylene-based resin, and a polyimide resin. However, the material of the first base substrate SUB1 is not limited to the aforementioned examples.

The circuit layer DP-CL may be arranged or provided on the first base substrate SUB1. The circuit layer DP-CL may include at least one insulating (e.g., electrically insulating) layer, a conductive (e.g., electrically conductive) pattern, and a semiconductor pattern. In one or more embodiments, a stacked structure of the circuit layer DP-CL may be modified in one or more suitable ways depending on the process step (e.g., act or task) of manufacturing the circuit layer DP-CL or the configuration or arrangement of elements included in the pixel, and FIG. 6 illustrates a stacked form of the circuit layer DP-CL according to one or more embodiments. However, this is merely illustrative, and the circuit layer DP-CL of the present disclosure is not limited to any one or more embodiments as long as the circuit layer DP-CL includes driving elements that drive the pixel.

The circuit layer DP-CL may include a light blocking pattern BML, the transistor TR, connecting electrodes CNE1 and CNE2, an insulating pattern GI, and a plurality of insulating layers INS10, INS11, and INS12.

The light blocking pattern BML may be arranged or provided on the first base substrate SUB1. The light blocking pattern BML may overlap the transistor TR. The light blocking pattern BML may prevent conductive (e.g., electrically conductive) patterns included in the circuit layer DP-CL from being visible due to external light (or reduce a degree or occurrence of being visible due to external light) or may prevent a semiconductor layer included in the transistor TR from being damaged by external light (or reduce a degree or occurrence of being damaged by external light).

The buffer layer BFL may be arranged or provided on the first base substrate SUB1 to cover a portion of the light blocking pattern BML. The buffer layer BFL may have a contact hole defined therein to expose a portion of the light blocking pattern BML. The buffer layer BFL may improve or enhance the coupling force between the first base substrate SUB1 and the semiconductor pattern.

The buffer layer BFL may include an inorganic material. For example, the buffer layer BFL may include at least one selected from among aluminum oxide, titanium oxide, silicon oxide, silicon nitride, silicon oxynitride, zirconium oxide, and hafnium oxide. However, the material of the buffer layer BFL is not limited thereto.

The semiconductor pattern of the transistor TR may be arranged or provided on the buffer layer BFL. The semiconductor pattern may include polysilicon. However, without being limited thereto, the semiconductor pattern may include amorphous (e.g., non-crystalline) silicon, crystalline oxide, or non-crystalline oxide.

A source area Sa, a drain area Da, and a channel area Aa of the transistor TR may be provided from the semiconductor pattern. The semiconductor pattern may be divided into a plurality of areas depending on conductivity (e.g., electrical or electron conductivity). For example, the electrical property of the semiconductor pattern may vary depending on whether doping is performed and/or whether metal oxide is reduced. A high conductivity (e.g., electrical conductivity) area of the semiconductor pattern may act or serve as an electrode or a signal line and may correspond to the source area Sa and the drain area Da of the transistor TR. A non-doped or non-reduced area having relatively low conductivity (e.g., electrical conductivity) may correspond to the channel area Aa (or the active area) of the transistor TR.

The insulating pattern GI may be provided by providing an insulating (e.g., electrically insulating) layer on the semiconductor pattern of the transistor TR and thereafter making the insulating (e.g., electrically insulating) layer subjected to patterning. A gate electrode Ga may be arranged or provided on the insulating pattern GI. The gate electrode Ga may be used as a mask in the process of providing the insulating pattern GI. The gate electrode Ga may overlap the channel area Aa. On the section, the gate electrode Ga may be spaced and/or apart (e.g., spaced apart or separated) from the semiconductor pattern of the transistor TR with the insulating pattern GI therebetween.

The plurality of insulating layers INS10, INS11, and INS12 may be arranged or provided on the buffer layer BFL. Each of the plurality of insulating layers INS10, INS11, and INS12 may include at least one inorganic film or at least one organic film. For example, the inorganic film of each of the insulating layers INS10, INS11, and INS12 may include at least one selected from among aluminum oxide, titanium oxide, silicon oxide, silicon nitride, silicon oxynitride, zirconium oxide, and hafnium oxide, but embodiments of the present disclosure are not limited thereto. The organic film of each of the insulating layers INS10, INS11, and INS12 may include a phenol-based polymer, an acryl-based polymer, an imide-based polymer, an aryl ether-based polymer, an amide-based polymer, a fluorine-based polymer, a p-xylene-based polymer, a vinyl alcohol-based polymer, and/or a (e.g., any suitable) combination thereof, but embodiments of the present disclosure are not limited thereto.

The first insulating layer INS10 may be arranged or provided on the buffer layer BFL and may cover the gate electrode Ga. The first insulating layer INS10 may have a contact hole defined therein to expose a portion of the semiconductor pattern of the transistor TR.

The connecting electrodes CNE1 and CNE2 may include a first connecting electrode CNE1 and a second connecting electrode CNE2 that are arranged or provided on the first insulating layer INS10. The first connecting electrode CNE1 may be connected to the source area Sa of the transistor TR through a contact hole penetrating the first insulating layer INS10. In one or more embodiments, the first connecting electrode CNE1 may be connected to the light blocking pattern BML through a contact hole penetrating the first insulating layer INS10 and the buffer layer BFL. The second connecting electrode CNE2 may be connected to the drain area Da of the transistor TR through a contact hole penetrating the first insulating layer INS10. The second connecting electrode CNE2 may extend on the plane and may be connected to another transistor or wiring (e.g., electrical wiring).

The second insulating layer INS11 and the third insulating layer INS12 may be arranged or provided on the first insulating layer INS10 to cover the connecting electrodes CNE1 and CNE2. A through-hole exposing a portion of the first connecting electrode CNE1 may be defined in the second insulating layer INS11 and the third insulating layer INS12, and the first connecting electrode CNE1 may be connected to a first electrode AE1 of the light emitting element OL arranged or provided on the third insulating layer INS12. In one or more embodiments, the third insulating layer INS12 may include an organic film and may provide a flat (e.g., substantially flat) upper surface. However, embodiments of the present disclosure are not necessarily limited thereto.

The light emitting element layer DP-OL may be arranged or provided on the circuit layer DP-CL. The light emitting element layer DP-OL may include a plurality of light emitting elements OL and a pixel defining layer PDL, and FIG. 6 illustrates a section that corresponds to one light emitting element OL among the plurality of light emitting elements OL. The light emitting element OL may be defined by the first electrode AE and a portion of a hole control layer HCL, a portion of an emissive layer EML, a portion of an electron control layer ECL, and a portion of a second electrode CE that are arranged or provided in a light emitting opening PX-OP to be described in more detail.

The display area DA may include the emissive area PXA that corresponds to the light emitting element OL and the non-emissive area NPXA around (e.g., surrounding) the emissive area PXA. The light emitting element OL may include the first electrode AE, the hole control layer HCL, the emissive layer EML, the electron control layer ECL, and the second electrode CE.

The first electrode AE may be arranged or provided on the upper surface of the third insulating layer INS12. The first electrode AE may be connected to the first connecting electrode CNE1 through a third contact hole that penetrates the second insulating layer INS11 and the third insulating layer INS12.

The pixel defining layer PDL may be arranged or provided on the third insulating layer INS12. The pixel defining layer PDL may have the light emitting opening PX-OP defined therein to expose a portion of the first electrode AE. The pixel defining layer PDL may cover a portion of the upper surface of the first electrode AE. In one or more embodiments, the portion of the first electrode AE exposed by the light emitting opening PX-OP may correspond to the emissive area PXA. The area where the pixel defining layer PDL is arranged or provided may correspond to the non-emissive area NPXA around (e.g., surrounding) the emissive area PXA.

The pixel defining layer PDL may include a polymer resin. For example, the pixel defining layer PDL may include a polyacrylate-based resin and/or a polyimide-based resin. The pixel defining layer PDL may further include an inorganic material, in addition to the polymer resin. Furthermore, the pixel defining layer PDL may include an inorganic material. For example, the pixel defining layer PDL may include silicon nitride (e.g., Si₃N₄ or SiNₓ, wherein 0<X≤2), silicon oxide (e.g., SiOₓ, where 0<x≤2; e.g., SiO₂), and/or silicon oxynitride (e.g., Si₂N₂O or SiO_{X}N_{Y}, wherein 0<X≤2 and 0≤Y≤2; e.g., SiON).

In one or more embodiments, the pixel defining layer PDL may include a light absorbing material. The pixel defining layer PDL may include a black coloring agent. The black coloring agent may include a black dye and/or a black pigment. The black coloring agent may include carbon black, metal, such as chromium, or oxide thereof. However, the pixel defining layer PDL is not limited thereto.

The hole control layer HCL may be arranged or provided on the first electrode AE and the pixel defining layer PDL. The hole control layer HCL may be arranged or provided for the plurality of pixels. A portion of the hole control layer HCL may be arranged or provided in the light emitting opening PX-OP. The hole control layer HCL may overlap the emissive area PXA and the non-emissive area NPXA. The hole control layer HCL may include at least one selected from among a hole transport layer and a hole injection layer.

The emissive layer EML may be arranged or provided on the hole control layer HCL. The emissive layer EML may be arranged or provided for the plurality of pixels. A portion of the emissive layer EML may be arranged or provided in the light emitting opening PX-OP and may overlap the emissive area PXA. The emissive layer EML may overlap the emissive area PXA and the non-emissive area NPXA.

The emissive layer EML may include an organic luminescent material, an inorganic luminescent material, quantum dots, and/or quantum rods. The emissive layer EML may be separately provided for each of the pixels in the form of a light emission pattern. However, without being limited thereto, the emissive layer EML may be provided as a common layer that is generally used or provided for the pixels. The emissive layer EML may generate the first light that is source light. For example, the first light may be blue light. However, embodiments of the present disclosure are not necessarily limited thereto.

In one or more embodiments, the light emitting element OL may be a light emitting element having a tandem structure that includes a plurality of emissive layers. The plurality of emissive layers may be stacked on the first electrode AE in the thickness direction. One or more of the plurality of emissive layers may generate light of substantially the same color, and the others may generate light of a different color. For example, the light emitting element OL according to one or more embodiments may include four emissive layers. Among the four emissive layers, three emissive layers may generate blue light, and one emissive layer may generate green light. However, this is merely illustrative, and the structure of the emissive layer EML is not necessarily limited thereto. The light emitting element having the tandem structure may further include functional layers, such as a hole control layer, an electron control layer, and a charge generation layer, which are arranged or provided between the plurality of emissive layers.

The electron control layer ECL may be arranged or provided on the emissive layer EML. The electron control layer ECL may be arranged or provided for the plurality of pixels. A portion of the electron control layer ECL may be arranged or provided in the light emitting opening PX-OP. The electron control layer ECL may overlap the emissive area PXA and the non-emissive area NPXA. The electron control layer ECL may include at least one selected from among an electron transport layer and an electron injection layer.

The second electrode CE may be arranged or provided on the electron control layer ECL. The second electrode CE may be arranged or provided for the plurality of pixels. The second electrode CE may overlap the emissive area PXA and the non-emissive area NPXA. A common voltage may be provided to the second electrode CE, and the second electrode CE may be referred to as a common electrode.

Through the transistor TR, a first voltage may be applied to the first electrode AE, and the common voltage may be applied to the second electrode CE. Holes and electrons injected into the emissive layer EML may be combined to provide excitons, and as the excitons transition to a ground state, the light emitting element OL may emit light.

The encapsulation layer TFE may be arranged or provided on the light emitting element layer DP-OL and may seal the light emitting element layer DP-OL. The encapsulation layer TFE may include a first encapsulation film EN1, a second encapsulation film EN2, and a third encapsulation film EN3. The first encapsulation film EN1 may be arranged or provided on the second electrode CE, and the second encapsulation film EN2 and the third encapsulation film EN3 may be sequentially arranged or provided on the first encapsulation film EN1.

In one or more embodiments, the first encapsulation film EN1 and the third encapsulation film EN3 may include an inorganic film, and the inorganic film may be to protect the light emitting element layer DP-OL from moisture and/or oxygen. For example, the inorganic film may include at least one selected from among aluminum oxide, titanium oxide, silicon oxide, silicon nitride, silicon oxynitride, zirconium oxide, and hafnium oxide, but embodiments of the present disclosure are not limited thereto.

In one or more embodiments, the second encapsulation film EN2 may include an organic film, and the organic film may protect the light emitting element layer DP-OL from foreign matter (e.g., undesirable impurities), such as dust particles. For example, the organic film may include an acrylic resin, but embodiments of the present disclosure are not limited thereto.

FIG. 7 is a sectional view (e.g., cross-sectional view) of a portion of the display module that corresponds to the line II-II′ illustrated in FIG. 5.

The circuit layer DP-CL is briefly illustrated as one layer.

The hole control layer HCL (refer to FIG. 6) and the electron control layer ECL (refer to FIG. 6) of the light emitting element OL are not provided.

Among the components illustrated in FIG. 7, components that are substantially identical to the components described with reference to the drawings according to one or more embodiments may not be provided in the description or may be briefly described.

Referring to FIG. 7, the light emitting opening PX-OP may be defined by the pixel defining layer PDL. The light emitting opening PX-OP may include a first light emitting opening PX-OP1, a second light emitting opening PX-OP2, and a third light emitting opening PX-OP3.

The first light emitting opening PX-OP1 may overlap the first emissive area PXA1. The second light emitting opening PX-OP2 may overlap the second emissive area PXA2. The third light emitting opening PX-OP3 may overlap the third emissive area PXA3.

The first light emitting opening PX-OP1 may overlap the first emissive area PXA1. The second light emitting opening PX-OP2 may overlap the second emissive area PXA2. The third light emitting opening PX-OP3 may overlap the third emissive area PXA3.

The third light emitting opening PX-OP3 may have a shorter length in the first direction DR1 than the first light emitting opening PX-OP1 and the second light emitting opening PX-OP2. The first light emitting opening PX-OP1 may have a shorter length in the first direction DR1 than the second light emitting opening PX-OP2.

Light emitting elements OL1, OL2, and OL3 may include a first light emitting element OL1, a second light emitting element OL2, and a third light emitting element OL3. The first light emitting element OL1 may be arranged or provided in the first light emitting opening PX-OP1 and may overlap the first emissive area PXA1. The second light emitting element OL2 may be arranged or provided in the second light emitting opening PX-OP2 and may overlap the second emissive area PXA2. The third light emitting element OL3 may be arranged or provided in the third light emitting opening PX-OP3 and may overlap the third emissive area PXA3.

The first light emitting element OL1, the second light emitting element OL2, and the third light emitting element OL3 may include first electrodes AE1, AE2, and AE3, emissive layers EML1, EML2, and EML3, and second electrodes CE1, CE2, and CE3, respectively.

The first electrodes AE1, AE2, and AE3 of the first light emitting element OL1, the second light emitting element OL2, and the third light emitting element OL3 may be spaced and/or apart (e.g., spaced apart or separated) from one another on the circuit layer DP-CL. In one or more embodiments, each of the first electrodes AE1, AE2, and AE3 of the first light emitting element OL1, the second light emitting element OL2, and the third light emitting element OL3 may be connected to a corresponding transistor of the circuit layer DP-CL. Each of the first electrodes AE1, AE2, and AE3 may be connected to other transistors and at least one capacitor by the transistor directly connected thereto. For example, each of the first electrodes AE1, AE2, and AE3 may be connected to a corresponding transistor of the circuit layer DP-CL. In one or more embodiments, each of the first electrodes AE1, AE2, and AE3 may be connected to other transistors and at least one capacitor through the transistor directly connected to it.

The filling member FL may be arranged or provided between the display panel DP and the light control member LCM. The filling member FL may fill the separation space between the display panel DP and the light control member LCM. However, without being limited thereto, the filling member FL may not be provided, and the light control member LCM may be directly arranged or provided on the display panel DP.

The light control member LCM may be arranged or provided on the filling member FL. The light control member LCM may be arranged or provided on the display panel DP. The filling member FL may be arranged or provided between the display panel DP and a second capping layer CP2 that will be described in more detail.

The light control member LCM may include the upper substrate SUB2, the color filter layer CFL, a low refractive index layer LR, a first capping layer CP1, the light control layer LCL, and the second capping layer CP2. The color filter layer CFL, the low refractive index layer LR, the first capping layer CP1, the light control layer LCL, and the second capping layer CP2 may be sequentially arranged or provided on the rear surface of the upper substrate SUB2 in the third direction DR3. The rear surface of the upper substrate SUB2 may be defined as a surface that is opposite to (e.g., faces) the upper surface of the lower substrate SUB1.

The light control layer LCL may include the light conversion layers WCP, the light transmitting layer LCP, a bank layer BK, and a spacer CS. The bank layer BK may be arranged or provided on the lower surface of the first capping layer CP1. The lower surface of the first capping layer CP1 may be defined as a surface that is opposite to (e.g., faces) the display panel DP. The bank layer BK may overlap the non-emissive area NPXA. Although a plurality of bank layers BK are illustrated when viewed in the second direction DR2, the bank layer BK may be substantially integrally provided.

The bank layer BK may include a black pigment and a water-repellent material. Because the bank layer BK includes the black pigment, the bank layer BK may be substantially black in color. In one or more embodiments, to prevent color mixing (or to reduce a degree or occurrence of color mixing) between light emitted from the light emitting elements OL1, OL2, and OL3, the bank layer BK may be to block the light. In one or more embodiments, the first emissive area PXA1, the second emissive area PXA2, and the third emissive area PXA3 may be surrounded by the bank layer BK in a plan view (when viewed from above a plane).

A plurality of openings OP1, OP2, and OP3 may be defined by the bank layer BK. The openings OP1, OP2, and OP3 may be spaced and/or apart (e.g., spaced apart or separated) from one another if (e.g., when) viewed in the second direction DR2. The first opening OP1 may overlap the third light emitting element OL3. The second opening OP2 may overlap the second light emitting element OL2. The third opening OP3 may overlap the first light emitting element OL1.

The light transmitting layer LCP may be arranged or provided between the display panel DP and the low refractive index layer LR. The light transmitting layer LCP may be arranged or provided on the lower surface of the first capping layer CP1. The lower surface of the first capping layer CP1 may be defined as a surface of the first capping layer CP1 that is opposite to (or faces) the display panel DP. The light transmitting layer LCP may be arranged or provided in the first opening OP1 defined by the bank layer BK.

The light transmitting layer LCP may overlap the third emissive area PXA3 and the non-emissive area NPXA adjacent to the third emissive area PXA3. The light transmitting layer LCP may overlap the third light emitting element OL3.

The light transmitting layer LCP may include a first base resin BR1 and scatterers SR dispersed or provided in the first base resin BR1. The scatterers SR may be to scatter light incident from the third light emitting element OL3 to the light transmitting layer LCP in one or more suitable directions. The scatterers SR may be particles having a relatively high density or specific gravity. For example, the scatterers SR may include titanium oxide (TiOₓ, where 0<x≤2) and/or silica-based nanoparticles. The scatterers SR may improve or enhance the light emission efficiency of light that is provided from the third light emitting element OL3 and that passes through the light transmitting layer LCP.

The light transmitting layer LCP may be to transmit first light provided from the third light emitting element OL3. For example, the third light emitting element OL3 may provide blue light to the light transmitting layer LCP, and the blue light may pass through the light transmitting layer LCP and may be output toward the front surface of the display module DM.

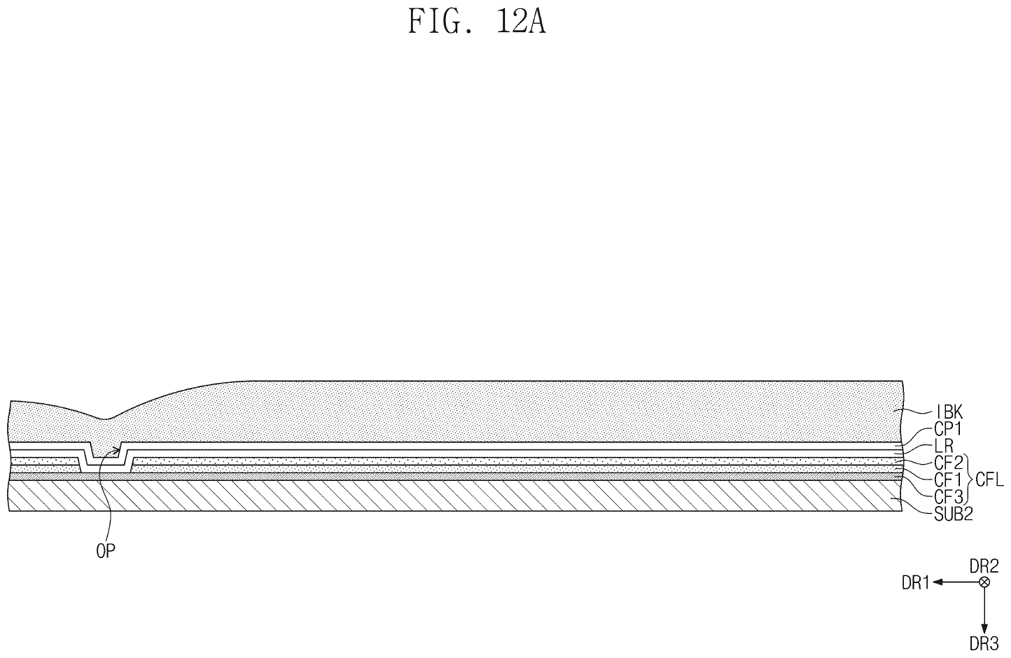

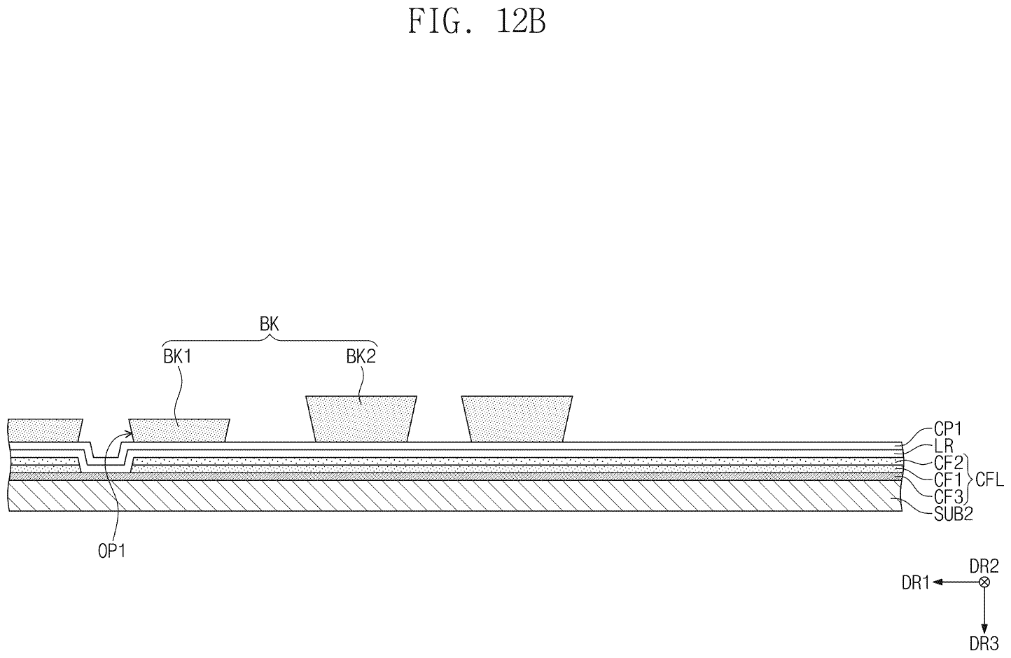

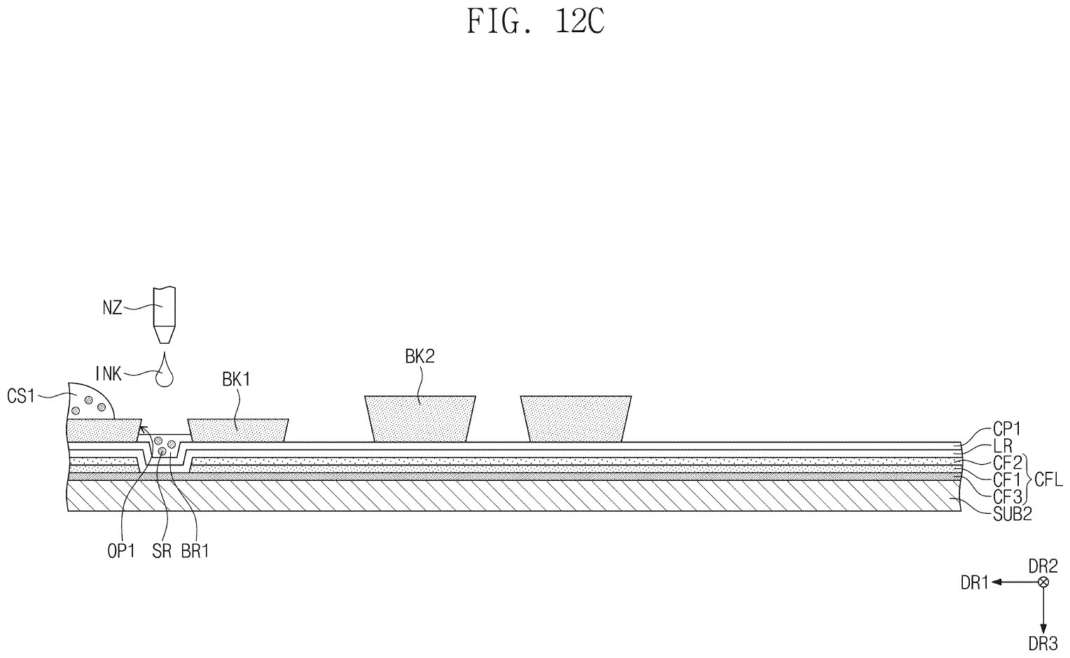

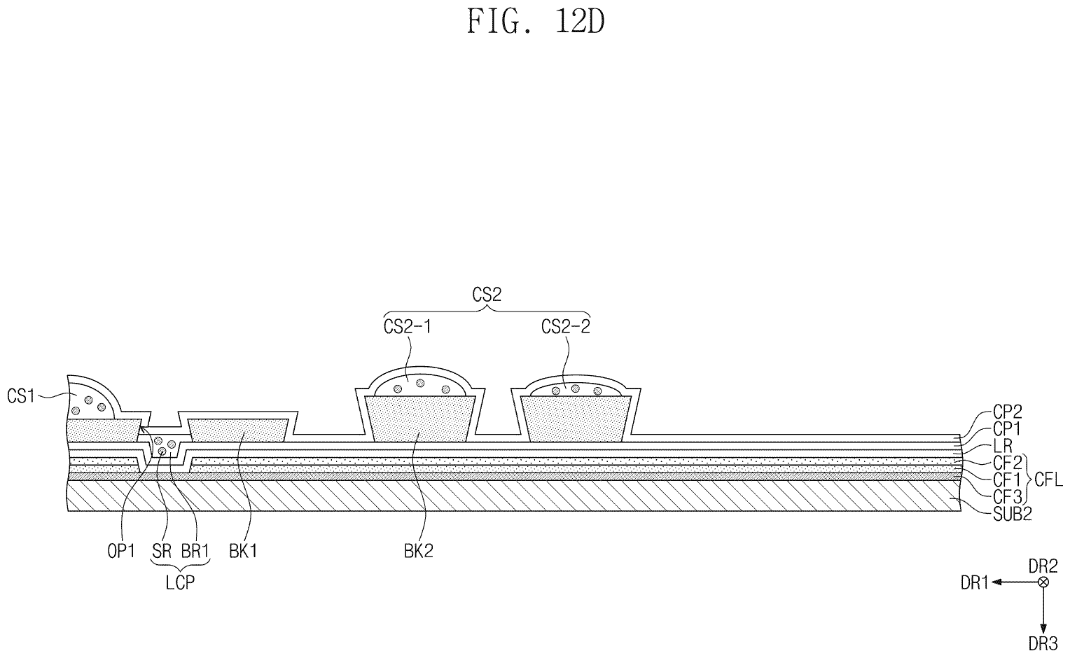

The light transmitting layer LCP may be provided through a photolithography process. The formation of the light transmitting layer LCP will be described in more detail with reference to FIG. 12C.

The light conversion layers WCP may be arranged or provided in the second opening OP2 and the third opening OP3. The light conversion layers WCP may be arranged or provided between the first capping layer CP1 and the second capping layer CP2. The light conversion layers WCP may be arranged or provided between the low refractive index layer LR and the display panel DP. The light conversion layers WCP and the light transmitting layer LCP may be arranged or provided on substantially the same layer.

The light conversion layers WCP may overlap the first emissive area PXA1 and the second emissive area PXA2. The light conversion layers WCP may overlap the first light emitting element OL1 and the second light emitting element OL2.

The light conversion layers WCP may include a first light conversion layer WCP1 and a second light conversion layer WCP2. The first light conversion layer WCP1 may be arranged or provided in the third opening OP3. The second light conversion layer WCP2 may be arranged or provided in the second opening OP2. The first light conversion layers WCP1, the second light conversion layers WCP2, and the light transmitting layer LCP may be arranged or provided in the first direction DR1 if (e.g., when) viewed in the second direction DR2.

The first light conversion layer WCP1 may overlap the first emissive area PXA1. The first light conversion layer WCP1 may overlap the first light emitting element OL1. The second light conversion layer WCP2 may overlap the second emissive area PXA2. The second light conversion layer WCP2 may overlap the second light emitting element OL2.

The second light conversion layer WCP2 may have a greater width in the first direction DR1 than the first light conversion layer WCP1 and the light transmitting layer LCP. The first light conversion layer WCP1 may have a greater width in the first direction DR1 than the light transmitting layer LCP. For example, if (e.g., when) viewed in the second direction DR2, the second light conversion layer WCP2 may have the greatest width, and the light transmitting layer LCP may have the smallest width.

The first light conversion layer WCP1 may include a second base resin BR2 and first quantum dots QD1 dispersed or provided in the second base resin BR2. The second light conversion layer WCP2 may include a third base resin BR3 and second quantum dots QD2 dispersed or provided in the third base resin BR3.

Cores of the quantum dots QD1 and QD2 included in the first light conversion layer WCP1 and the second light conversion layer WCP2, respectively, may be selected from among a Group II-VI compound, a Group III-VI compound, a Group I-III-VI compound, a Group III-V compound, a Group IV-VI compound, a Group IV element, a Group IV compound, and/or a (e.g., any suitable) combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and/or a (e.g., any suitable) mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) mixture thereof, and a quarternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or a (e.g., any suitable) mixture thereof.

The Group III-VI compound may include a binary compound, such as In₂S₃ and/or In₂Se₃, a ternary compound, such as InGaS₃ and/or InGaSe₃, and/or a (e.g., any suitable) combination thereof.

The Group I-III-VI compound may be selected from among a ternary compound selected from the group consisting of AgInS, AgInS₂, CuInS, CuInS₂, AgGaS₂, CuGaS₂, CuGaO₂, AgGaO₂, AgAlO₂, and/or a (e.g., any suitable) mixture thereof or a quarternary compound, such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and/or a (e.g., any suitable) mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or a (e.g., any suitable) mixture thereof, and a quarternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a (e.g., any suitable) mixture thereof. In one or more embodiments, the Group III-V compound may further include Group II metal. For example, InZnP may be selected as a Group III-II-V compound.

The Group IV-VI compound may be selected from the group consisting of a binary compound selected from the group consisting of SnS, SnSe, SnTe, PbS, PbSe, PbTe, and/or a (e.g., any suitable) mixture thereof, a ternary compound selected from the group consisting of SnSeS, SnSeTe, SnSTe, PbSeS, PbSeTe, PbSTe, SnPbS, SnPbSe, SnPbTe, and/or a (e.g., any suitable) mixture thereof, and a quarternary compound selected from the group consisting of SnPbSSe, SnPbSeTe, SnPbSTe, and/or a (e.g., any suitable) mixture thereof. The Group IV element may be selected from the group consisting of Si, Ge, and/or a (e.g., any suitable) mixture thereof. The Group IV compound may be a binary compound selected from the group consisting of SiC, SiGe, and/or a (e.g., any suitable) mixture thereof.

The elements included in the multi-element compounds, such as the binary compounds, the ternary compounds, and the quarternary compounds, may exist in particles at substantially uniform or substantially non-uniform concentrations. For example, the chemical formulas may refer to the types or kinds of elements included in the compounds, and the element ratios within the compounds may be substantially different from one another. For example, AgInGaS₂ may refer to AgInxGa1-xS₂ (x being a real number between 0 and 1).

In one or more embodiments, the quantum dots may have a single structure or a core-shell dual structure in which the concentrations of elements included in a corresponding quantum dot are substantially uniform. For example, the material included in the core and the material included in the shell may be substantially different from each other.

In one or more embodiments, the quantum dots QD1 and QD2 may have the core-shell structure, as described in one or more embodiments, including a nanocrystal. The shell of each quantum dot may act or serve as a protective layer to maintain semiconductor characteristics by preventing chemical modification (or by reducing a degree or occurrence of chemical modification) of the core and/or a charging layer to impart or increase electrophoretic characteristics to the quantum dot. The shell may have a single layer or multiple layers. The interface between the core and the shell may have a concentration gradient in which the concentration of an element existing in the shell is decreased toward the center. The shell of the quantum dot may be exemplified by metal oxide, non-metal oxide, a semiconductor compound, and/or a (e.g., any suitable) combination thereof.

For example, the metal oxide and the non-metal oxide may include, but are not limited to, a binary compound, such as SiO₂, AL₂O₃, TiO₂, ZnO, MnO, Mn₂O₃, CuO, FeO, Fe₂O₃, Fe₃O₄, CoO, Co₃O₄, and/or NiO, and/or a ternary compound, such as MgAl₂O₄, CoFe₂O₄, NiFe₂O₄, and/or CoMn₂O₄.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb, but the material is not limited to the examples.

The elements included in the multi-element compounds, such as the binary compounds and the ternary compounds, may exist in particles at substantially uniform or substantially non-uniform concentrations. For example, the chemical formulas may refer to the types or kinds of elements included in the compounds, and the element ratios within the compounds may be substantially different from one another.

The quantum dots QD1 and QD2 may have a full width of half maximum (FWHM) of a light emission wavelength spectrum of about 45 nm or less, for example, about 40 nm or less, and, for example, about 30 nm or less and may improve or enhance color purity or color reproduction in the range. Furthermore, light emitted through the quantum dots QD1 and QD2 may be emitted in all directions, and thus a wide viewing angle may be improved or enhanced.

The forms of the quantum dots QD1 and QD2 are not particularly limited to forms generally used in the related art. For example, nanoparticles, nanotubes, nanowires, nanofibers, or nanoplatelet particles that have a spherical (e.g., substantially spherical), pyramidal (e.g., substantially pyramidal), multi-arm (e.g., substantially multi-arm), or cubic (e.g., substantially cubic) shape may be used.

The quantum dots QD1 and QD2 may be to adjust the color of emitted light by adjusting the particle size or the element ratio in the compound. In one or more embodiments, the quantum dots QD1 and QD2 may have one or more suitable light emission colors, such as blue, red, and green. In one or more embodiments, the first quantum dots QD1 may be to convert first light provided by the first light emitting element OL1 into second light having a wavelength range substantially different from that of the first light. For example, the first quantum dots QD1 may be to convert the first light provided by the first light emitting element OL1 into red light. In one or more embodiments, the display module DM may be to output the red light through the first emissive area PXA1.

The second quantum dots QD2 may be to convert first light provided by the second light emitting element OL2 into third light having a wavelength range substantially different from that of the first light. Here, the second light and the third light may have substantially different wavelength ranges. For example, the second quantum dots QD2 may be to convert the first light provided by the second light emitting element OL2 into green light. In one or more embodiments, the display module DM may be to output the green light through the second emissive area PXA2.

The low refractive index layer LR may be arranged or provided between the light control layer LCL and the color filter layer CFL. The low refractive index layer LR may have a refractive index lower than the refractive indexes of the first light conversion layer WCP1, the second light conversion layer WCP2, and the light transmitting layer LCP. For example, the low refractive index layer LR may have a refractive index of about 1.1 to about 1.5. For example, the low refractive index layer LR may have a refractive index of about 1.1 to about 1.35. However, the refractive index of the low refractive index layer LR is not limited to the numerical example. The low refractive index layer LR may include a low refractive index organic film having a relatively low refractive index. The low refractive index layer LR may further include hollow particles and/or voids dispersed or provided in the organic film. The refractive index of the low refractive index layer LR may be adjusted by the percentage of the hollow particles and/or the voids.

The low refractive index layer LR arranged or provided over the light control layer LCL may be to input light that is not converted by the light conversion layers WCP1 and WCP2 and output from the upper surfaces of the light conversion layers WCP1 and WCP2 into the light conversion layers WCP1 and WCP2 by using the refractive index of the low refractive index layer LR. The light input into the light conversion layers WCP1 and WCP2 by the low refractive index layer LR may be converted by the quantum dots QD1 and QD2. For example, the low refractive index layer LR may improve or enhance the light emission efficiency of the display device DD (refer to FIG. 1) through the light recirculation by utilizing the refractive index of the low refractive index layer LR.

The low refractive index layer LR may include a material having a high light transmittance. For example, the low refractive index layer LR may have a high light transmittance of about 90% or more. Because the low refractive index layer LR has a high light transmittance, the transmittance of light output toward the front surface of the display module DM may not be lowered.

The first capping layer CP1 may be arranged or provided on the lower surface of the low refractive index layer LR that is opposite to (or faces) the display panel DP. The first capping layer CP1 may include an inorganic material. The first capping layer CP1 may prevent infiltration (or reduce a degree or occurrence of infiltration) of moisture and/or gas into the low refractive index layer LR.

The spacer CS may be arranged or provided on the rear surface of the bank layer BK that is adjacent to the light transmitting layer LCP. The rear surface of the bank layer BK may be defined as a surface that is opposite to (e.g., faces) the display panel DP. Although the spacer CS is arranged or provided on the rear surface of the bank layer BK that is adjacent to the light transmitting layer LCP, the position of the spacer CS may be varied or adjusted.

The spacer CS may extend toward the display panel DP if (e.g., when) viewed in the second direction DR2. The spacer CS may maintain the gap between the display panel DP and the light control member LCM. For example, the spacer CS may act or serve to maintain the cell gap (or the gap) between the display panel DP and the light control member LCM.

The outer surface of the spacer CS may have a set or predetermined curvature if (e.g., when) viewed in the second direction DR2. For example, the spacer CS may have the shape of a portion of an ellipse (e.g., substantially ellipse) if (e.g., when) viewed in the second direction DR2. The outer surface of the spacer CS may be defined as a surface that is opposite to (e.g., faces) the display panel DP.

The spacer CS may include a first base resin BR1 and scatterers SR. The spacer CS may include substantially the same material as the light transmitting layer LCP. The spacer CS may be concurrently (e.g., simultaneously) provided with the light transmitting layer LCP. The spacer CS may be concurrently (e.g., simultaneously) provided with the light transmitting layer LCP through a photolithography process. The formation of the light transmitting layer LCP and the spacer CS will be described in more detail with reference to FIG. 12C.

The second capping layer CP2 may be arranged or provided on the lower surface of the light control layer LCL that is opposite to (or faces) the display panel DP. The second capping layer CP2 may cover the bank layer BK, the spacer CS, the light transmitting layer LCP, and the light conversion layers WCP.

The second capping layer CP2 may prevent infiltration (or reduce a degree or occurrence of infiltration) of moisture and/or foreign matter (e.g., undesirable impurities) into the light control layer LCL. The first capping layer CP1 and the second capping layer CP2 may cover the top and bottom of the light control layer LCL to protect the light control layer LCL and prevent deterioration (or reduce a degree or occurrence of deterioration) due to moisture.

The color filter layer CFL may include the first color filter CF1, the second color filter CF2, and the third color filter CF3. The first color filter CF1, the second color filter CF2, and the third color filter CF3 may be arranged or provided to correspond to the first emissive area PXA1, the second emissive area PXA2, and the third emissive area PXA3, respectively, in a plan view (when viewed from above a plane). For example, the first color filter CF1 may overlap the first emissive area PXA1, the second color filter CF2 may overlap the second emissive area PXA2, and the third color filter CF3 may overlap the third emissive area PXA3.

Each of the first color filter CF1, the second color filter CF2, and the third color filter CF3 may include a base resin and a pigment or dye dispersed or provided in the base resin. Each of the first color filter CF1, the second color filter CF2, and the third color filter CF3 may be to transmit light having a set or predetermined wavelength range and may be to absorb most of light having a wavelength range other than the set or predetermined wavelength range.

For example, the first color filter CF1 may include a red color filter. The second color filter CF2 may include a green color filter. The third color filter CF3 may include a blue color filter. The red color filter may be to transmit red light and may be to absorb most of green light and blue light. The green color filter may be to transmit green light and may be to absorb most of red light and blue light. The blue color filter may be to transmit blue light and may be to absorb most of red light and green light.

The first color filter CF1 may be arranged or provided over the first light conversion layer WCP1. The first color filter CF1 may be to transmit the second light provided from the first light conversion layer WCP1. For example, the first light conversion layer WCP1 may be to convert the first light provided from the first light emitting element OL1 into red light, and the first color filter CF1 may be to transmit the red light provided from the first light conversion layer WCP1. The first color filter CF1 may be to absorb green light and blue light incident toward the first color filter CF1. The first color filter CF1 may be to absorb light beams not converted by the first light conversion layer WCP1 among light beams incident toward the first color filter CF1, thereby preventing deterioration (or reducing a degree or occurrence of deterioration) in color purity in the first emissive area PXA1.

The second color filter CF2 may be arranged or provided over the second light conversion layer WCP2 and may be to transmit the third light provided from the second light conversion layer WCP2. For example, the second light conversion layer WCP2 may be to convert the first light provided from the second light emitting element OL2 into green light, and the second color filter CF2 may be to transmit the green light provided from the second light conversion layer WCP2. The second color filter CF2 may be to absorb red light and blue light incident toward the second color filter CF2. The second color filter CF2 may be to absorb light beams not converted by the second light conversion layer WCP2 among light beams incident toward the second color filter CF2, thereby preventing deterioration (or reducing a degree or occurrence of deterioration) in color purity in the second emissive area PXA2.

The third color filter CF3 may be arranged or provided over the light transmitting layer LCP. The third color filter CF3 may overlap the light transmitting layer LCP. The third color filter CF3 may be to transmit the first light that is provided from the third light emitting element OL3 and that passes through the light transmitting layer LCP. For example, the third color filter CF3 may be to transmit blue light and may be to absorb green light and red light, thereby preventing deterioration (or reducing a degree or occurrence of deterioration) in color purity in the third emissive area PXA3.

External light, such as natural light, may be incident toward the display module DM from outside the display module DM. The external light may include red light, green light, and/or blue light. If (e.g., when) the display module DM does not include the color filter layer CFL, the external light incident toward the display module DM may be reflected by conductive (e.g., electrically conductive) patterns (e.g., signal lines and electrodes) in the display module DM and may be provided to the user, and the user may visually recognize the reflected light.

The first color filter CF1, the second color filter CF2, and the third color filter CF3 may be to prevent the reflection (or reduce a degree or occurrence of the reflection) of external light. For example, the first color filter CF1 may be a red color filter. The first color filter CF1 may be to filter the external light into red light by absorbing light that corresponds to green light and blue light of the external light. Likewise, the second color filter CF2 may be a green color filter. The second color filter CF2 may be to filter the external light into green light by absorbing light that corresponds to red light and blue light of the external light. The third color filter CF3 may be a blue color filter. The third color filter CF3 may be to filter the external light into blue light by absorbing light that corresponds to red light and green light of the external light.

At least two color filters selected from among the first color filter CF1, the second color filter CF2, and the third color filter CF3 may overlap each other in the non-emissive area NPXA. For example, the first color filter CF1, the second color filter CF2, and the third color filter CF3 may be arranged or provided to overlap each other in the third direction DR3 in the non-emissive area NPXA. For example, the first color filter CF1 may be arranged or provided under the third color filter CF3, and the second color filter CF2 may be arranged or provided under the first color filter CF1.

The first color filter CF1, the second color filter CF2, and the third color filter CF3 arranged or provided to overlap each other may extend above the bank layer BK and may overlap each other. The first color filter CF1, the second color filter CF2, and the third color filter CF3 arranged or provided to overlap each other may be to block light that passes through the non-emissive area NPXA to prevent color mixing (or to reduce a degree or occurrence of color mixing) between the emissive areas (e.g., between the first emissive area PXA1 and the second emissive area PXA2, between the first emissive area PXA1 and the third emissive area PXA3, and between the second emissive area PXA2 and the third emissive area PXA3).

The upper substrate SUB2 may be arranged or provided on the color filter layer CFL. The upper substrate SUB2 may include a glass substrate, a polymer substrate, and/or an organic/inorganic composite substrate. The upper substrate SUB2 may include a front surface and a rear surface that are substantially parallel to the first direction DR1 and the second direction DR2. The rear surface of the upper substrate SUB2 may be opposite to (or face) the upper surface of the lower substrate SUB1. The upper substrate SUB2 may provide a base surface on which the components of the light control layer LCM are stacked.

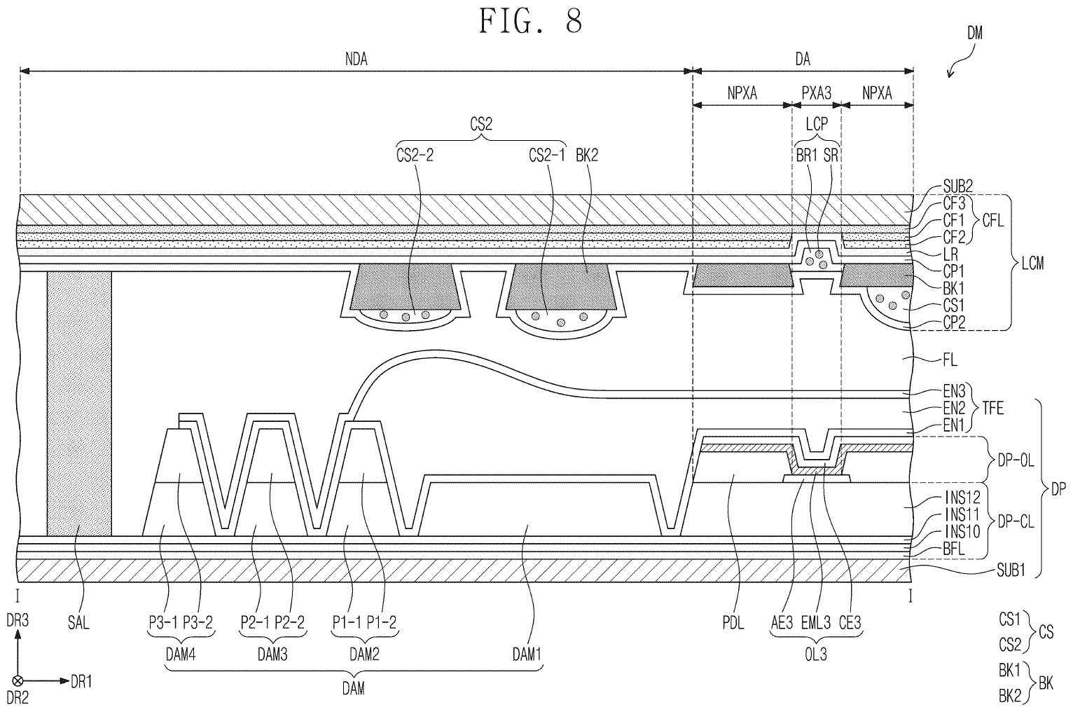

FIG. 8 is a sectional view (e.g., cross-sectional view) taken along the line I-I′ illustrated in FIG. 2.

FIG. 8 illustrates sections of the display module DM that correspond to the peripheral area NDA where the sealing member SAL is arranged or provided and the display area DA adjacent to the peripheral area NDA.

In FIG. 8, the third light emitting element OL3 and the light transmitting layer LCP that correspond to the third emissive area PXA3 arranged or provided adjacent to the peripheral area NDA are illustrated.

Among the components illustrated in FIG. 8, components that are substantially identical to the components described with reference to the drawings according to one or more embodiments may not be provided in the description or may be briefly described.

Referring to FIG. 8, the buffer layer BFL, the first insulating layer INS10, and the second insulating layer INS11 arranged or provided on the upper surface of the lower substrate SUB1 may extend from the display area DA toward the peripheral area NDA. The sealing member SAL according to one or more embodiments may be arranged or provided on the upper surface of the second insulating layer INS11 that corresponds to the peripheral area NDA. However, embodiments of the present disclosure are not necessarily limited thereto, and the position of the sealing member SAL may vary depending on the arrangement of the insulating (e.g., electrically insulating) layers of the display panel DP. For example, the sealing member SAL may be arranged or provided on the first insulating layer INS10 or may be brought into contact with the lower substrate SUB1.

In one or more embodiments, one or more of (e.g., selected from among) the conductive (e.g., electrically conductive) patterns of the circuit layer DP-CL may be arranged or provided between the insulating (e.g., electrically insulating) layers in the peripheral area NDA. In one or more embodiments, the conductive (e.g., electrically conductive) patterns may overlap the sealing member SAL in a plan view (when viewed from above a plane).

The display panel DP may include a plurality of dams DAM1, DAM2, DAM3, and DAM4 that are arranged or provided in the peripheral area NDA. The plurality of dams DAM1, DAM2, DAM3, and DAM4 may be arranged or provided on the lower substrate SUB1. The dams DAM1, DAM2, DAM3, and DAM4 may be arranged or provided on the second insulating layer INS11.

The dams DAM1, DAM2, DAM3, and DAM4 may include a first dam DAM1, a second dam DAM2, a third dam DAM3, and a fourth dam DAM4 that are spaced and/or apart (e.g., spaced apart or separated) from one another in one direction. Among the dams DAM1, DAM2, DAM3, and DAM4, the first dam DAM1 may be arranged or provided closest to the display area DA. The fourth dam DAM4 may be arranged or provided farthest from the display area DA. Although the four dams DAM1, DAM2, DAM3, and DAM4 are illustrated as an example, the number of dams is not limited thereto.

At least one or more of the dams DAM1, DAM2, DAM3, and DAM4 may have a stacked structure that is substantially different from those of the other dams. For example, the first dam DAM1 may include substantially the same material as the third insulating layer INS12. The second dam DAM2 may include a first-first film P1-1 and a first-second film P1-2 sequentially stacked in the third direction DR3. The third dam DAM3 may include a second-first film P2-1 and a second-second film P2-2 sequentially stacked in the third direction DR3. The fourth dam DAM4 may include a third-first film P3-1 and a third-second film P3-2 sequentially stacked in the third direction DR3. The first-first film P1-1, the second-first film P2-1, and the third-first film P3-1 may include substantially the same material as the third insulating layer INS12, and the first-second film P1-2, the second-second film P2-2, and the third-second film P3-2 may include substantially the same material as the pixel defining layer PDL.

The first dam DAM1, the first-first film P1-1, the second-first film P2-1, and the third-first film P3-1 may be concurrently (e.g., simultaneously) provided in the process of providing the third insulating layer INS12, and the first-second film P1-2, the second-second film P2-2, and the third-second film P3-2 may be concurrently (e.g., simultaneously) provided in the process of providing the pixel defining layer PDL. However, without being limited thereto, the plurality of dams DAM1, DAM2, DAM3, and DAM4 may all include substantially the same material.

At least one or more of (e.g., selected from among) the plurality of dams DAM1, DAM2, DAM3, and DAM4 may have a height that is substantially different from those of the other dams in the third direction DR3. For example, the first dam DAM1 may have a lower height than the second dam DAM2, the third dam DAM3, and the fourth dam DAM4. However, without being limited thereto, the plurality of dams DAM1, DAM2, DAM3, and DAM4 may have substantially the same height.

The first encapsulation film EN1 of the encapsulation layer TFE may extend from the display area DA toward the peripheral area NDA and may be arranged or provided on the plurality of dams DAM1, DAM2, DAM3, and DAM4. The first encapsulation film EN1 of the encapsulation layer TFE may be brought into contact with the plurality of dams DAM1, DAM2, DAM3, and DAM4. The first encapsulation film EN1 may cover the first dam DAM1, the second dam DAM2, and the third dam DAM3. The first encapsulation film EN1 may cover one side of the fourth dam DAM4 in the first direction DR1 and a portion of the upper surface of the fourth dam DAM4. The opposite side of the fourth dam DAM4 and a portion of the upper surface of the fourth dam DAM4 may be exposed from the first encapsulation film EN1 to the outside. The one side of the fourth dam DAM4 in the first direction DR1 may be defined as a side adjacent to the display area DA.

The second encapsulation film EN2 of the encapsulation layer TFE may be arranged or provided on the first encapsulation film EN1. The formation area of the second encapsulation film EN2 including an organic film may be divided by the dams DAM1, DAM2, DAM3, and DAM4. In the process of manufacturing the display panel DP, the second encapsulation film EN2 having fluidity may flow toward the peripheral area NDA and may then be blocked by one of the dams DAM1, DAM2, DAM3, and DAM4. FIG. 8 illustrates an example that the flow of the second encapsulation film EN2 is blocked in the space between the first dam DAM1 and the second dam DAM2.

The upper surface of the second encapsulation film EN2 arranged or provided in the peripheral area NDA may protrude further toward the light control member LCM than the upper surface of the second encapsulation film EN2 arranged or provided in the display area DA. The height of the upper surface of the second encapsulation film EN2 arranged or provided in the peripheral area NDA may be greater than the height of the upper surface of the second encapsulation film EN2 arranged or provided in the display area DA. In one or more embodiments, the distance between the upper surface of the second encapsulation film EN2 and the lower surface of the bank layer BK may be smaller in the peripheral area NDA than in the display area DA.

The third encapsulation film EN3 may be arranged or provided on the second encapsulation film EN2 to cover the second encapsulation film EN2. The third encapsulation film EN3 may have a shape that corresponds to the upper surface of the second encapsulation film EN2. The third encapsulation film EN3 may extend further toward the outside of the peripheral area NDA than the second encapsulation film EN2. The third encapsulation film EN3 may be arranged or provided on the second dam DAM2 that is to block the flow of the second encapsulation film EN2 and may be arranged or provided on the third dam DAM3 and the fourth dam DAM4 arranged or provided outward of the second dam DAM2. The third encapsulation film EN3 may make contact with the first encapsulation film EN1 arranged or provided on the second dam DAM2, the third dam DAM3, and the fourth dam DAM4 and may seal the second encapsulation film EN2 together with the first encapsulation film EN1. In one or more embodiments, moisture and/or oxygen may be prevented from infiltrating into the second encapsulation film EN2 from the outside (or a degree or occurrence of infiltration of moisture and/or oxygen into the second encapsulation film EN2 from the outside may be reduced).

The dams DAM1, DAM2, DAM3, and DAM4 may be spaced and/or apart (e.g., spaced apart or separated) from the sealing member SAL in a plan view (when viewed from above a plane). The dams DAM1, DAM2, DAM3, and DAM4 may prevent the encapsulation layer TFE from extending to the outside of the peripheral area NDA where the sealing member SAL is arranged or provided.

The bank layer BK may include a first bank layer BK1 and a second bank layer BK2. The first bank layer BK1 may be defined as a bank layer BK arranged or provided in the display area DA. The second bank layer BK2 may be defined as a bank layer BK arranged or provided in the peripheral area NDA. Although the first bank layer BK1 and the second bank layer BK2 are spaced and/or apart (e.g., spaced apart or separated) from each other in FIG. 8, the first bank layer BK1 and the second bank layer BK2 may be substantially integrally provided with each other.

The thickness of the second bank layer BK2 may be greater than the thickness of the first bank layer BK1. The lower surface of the second bank layer BK2 may be closer to the lower substrate SUB1 than the lower surface of the first bank layer BK1. The lower surface of the first bank layer BK1 and the lower surface of the second bank layer BK2 may be defined as surfaces that are opposite to (e.g., face) the display panel DP. A difference in thickness between the first bank layer BK1 and the second bank layer BK2 will be described in more detail with reference to FIGS. 12A and 12B.

The spacer CS may include a first spacer CS1 and a plurality of second spacers CS2. The first spacer CS1 may be arranged or provided in the display area DA. The first spacer CS1 may be arranged or provided on the lower surface of the first bank layer BK1.

The plurality of second spacers CS2 may be arranged or provided at (in) the peripheral area NDA. The plurality of second spacers CS2 may be arranged or provided on the lower surface of the second bank layer BK2. The thicknesses of the plurality of second spacers CS2 may be smaller than the thickness of the first spacer CS1. The curvature of the outer surface of the first spacer CS1 may be greater than the curvatures of the outer surfaces of the plurality of second spacers CS2.

The thickness of the first spacer CS1 and the thicknesses of the plurality of second spacers CS2 may be adjusted by the amount of an ink INK (refer to FIG. 12C). More detailed description thereabout will be provided.

Because the thicknesses of the plurality of second spacers CS2 are smaller than the thickness of the first spacer CS1, the thickness difference between the first bank BK1 and the second bank layer BK2 may be compensated for. In one or more embodiments, the encapsulation layer TFE arranged or provided in the peripheral area NDA may protrude upward, and thus the encapsulation layer TFE and the plurality of second spacers CS2 may be prevented from making contact with each other (or a degree or occurrence of making contact with each other may be reduced).

In one or more embodiments, the ink may include a first ink and a second ink. The first ink and the second ink may be substantially the same. The first ink and the second ink may be substantially different. The first ink may be discharged into a first opening defined by the bank layer to provide a light transmitting layer. The second ink may be discharged onto a bank layer to provide a spacer.

The plurality of second spacers CS2 may include a second-first spacer CS2-1 and a second-second spacer CS2-2. The second-first spacer CS2-1 may be closer to the display area DA than the second-second spacer CS2-2. The thickness of the second-first spacer CS2-1 may be greater than the thickness of the second-second spacer CS2-2.

If (e.g., when) the display panel DP and the light control member LCM are bonded to each other, the portion of the encapsulation layer TFE arranged or provided in the peripheral area NDA may protrude further toward the light control member LCM than the portion of the encapsulation layer TFE that is adjacent to the boundary between the display area DA and the peripheral area NDA. The gap between the second bank layer BK2 and the encapsulation layer TFE may be smaller than the gap between the first bank layer BK1 and the encapsulation layer TFE. In one or more embodiments, if (e.g., when) the thickness of the second-second spacer CS2 is substantially equal to the thickness of the first spacer CS1, the second-second spacer CS2-2 and the encapsulation layer TFE may be brought into contact with each other. Therefore, the second-second spacer CS2-2 may be damaged, and a defect may occur in the non-display part D-NDA of the display device DD (refer to FIG. 1).

However, according to one or more embodiments of the present disclosure, the plurality of second spacers CS2 may have decreasing thicknesses as the plurality of second spacers CS2 are located farther away from the display area DA. For example, the thickness of the second-second spacer CS2-2 may be smaller than the thickness of the second-first spacer CS2-1. As the thickness of the second-second spacer CS2-2 is decreased, the gap between the second-second spacer CS2-2 and the encapsulation layer TFE may be increased. In one or more embodiments, if (e.g., when) the display panel DP and the light control member LCM are bonded to each other, the second-second spacer CS2-2 may not be brought into contact with the encapsulation layer TFE and thus may not be damaged.

The low refractive index layer LR, the first capping layer CP1, and the second capping layer CP2 may extend from the display area DA to the outside of the peripheral area NDA. The second capping layer CP2 may be arranged or provided in the display area DA and the peripheral area NDA. In the peripheral area NDA, the second capping layer CP2 may substantially completely cover the second bank layer BK2 and the plurality of second spacers CS2.

The sealing member SAL may be arranged or provided on the lower surface of the second capping layer CP2 that is opposite to (or faces) the display panel DP.

The first color filter CF1, the second color filter CF2, and the third color filter CF3 that are arranged or provided to overlap one another in the thickness direction may be to block light from being emitted or introduced through the peripheral area NDA. In one or more embodiments, the first color filter CF1, the second color filter CF2, and the third color filter CF3 that are arranged or provided to overlap one another in the third direction DR3 may prevent the reflection (or may reduce a degree or occurrence of the reflection) of external light incident toward the peripheral area NDA. In one or more embodiments, the order in which the first color filter CF1, the second color filter CF2, and the third color filter CF3 are stacked is not limited to that illustrated in FIG. 8 and may vary depending on the order in which the first color filter CF1, the second color filter CF2, and the third color filter CF3 are provided in the process step (e.g., act or task) of the light control member LCM.

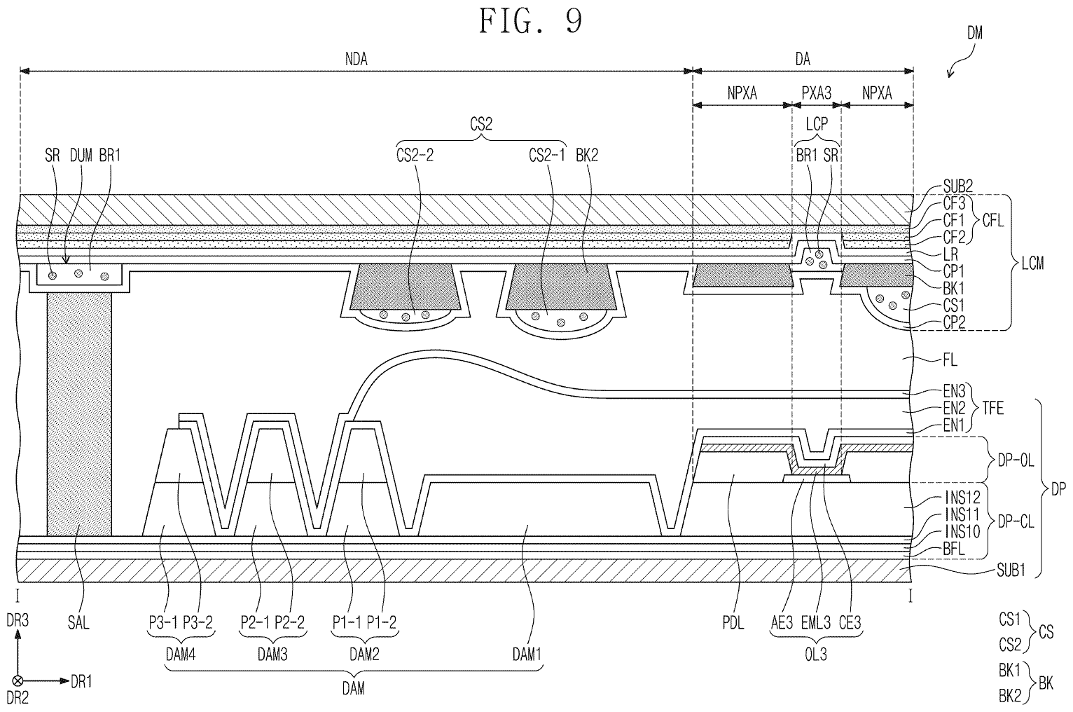

FIG. 9 is a sectional view (e.g., cross-sectional view) of the display module according to one or more embodiments of the present disclosure.

FIG. 9 is a sectional view (e.g., cross-sectional view) of a portion that corresponds to the line I-I′ illustrated in FIG. 2.

Among the components illustrated in FIG. 9, components that are substantially identical to the components described with reference to the drawings according to one or more embodiments may not be provided in the description or may be briefly described.

Referring to FIG. 9, the light control member LCM may further include a dummy part DUM. The dummy part DUM may be arranged or provided in the peripheral area NDA. The dummy part DUM may be arranged or provided on the lower surface of the first capping layer CP1 that is opposite to (or faces) the display panel DP. The dummy part DUM may be covered by the second capping layer CP2. The dummy part DUM may overlap the sealing member SAL.

The dummy part DUM may include substantially the same material as the light transmitting layer LCP. The dummy part DUM may be concurrently (e.g., simultaneously) provided with the light transmitting layer LCP. The dummy part DUM may include a first base resin BR1 and scatterers SR.

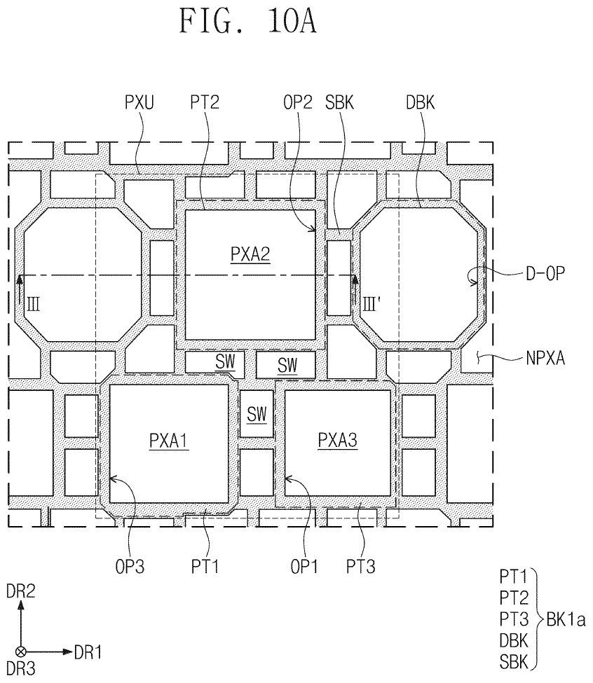

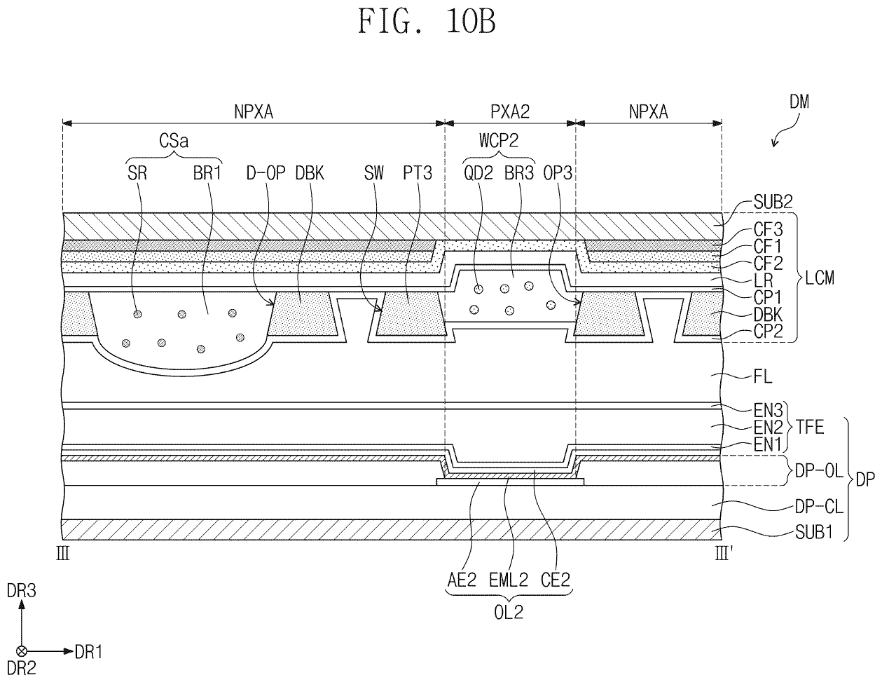

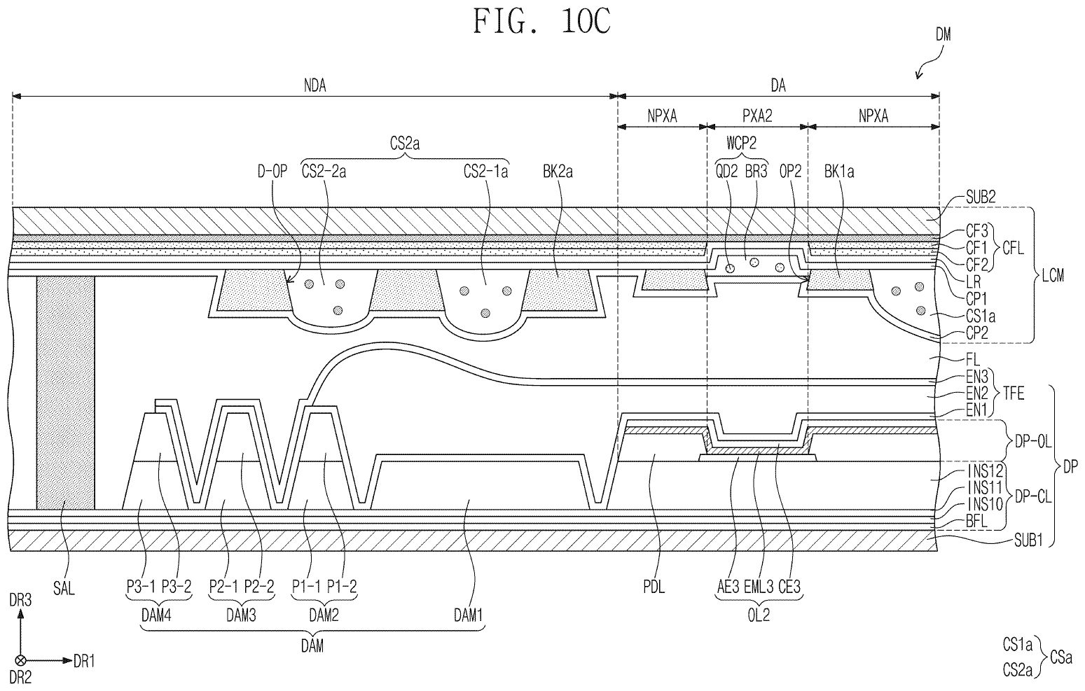

FIG. 10A is a plan view of the light control member according to one or more embodiments of the present disclosure. FIG. 10B is a sectional view (e.g., cross-sectional view) of a portion that corresponds to the line III-III′ illustrated in FIG. 10A. FIG. 10C is a view to illustrate the peripheral area of the display device including a bank layer illustrated in FIG. 10A.

FIG. 10A illustrates a portion that corresponds to the display area DA (refer to FIG. 4). Furthermore, FIG. 10A is a plan view of the lower surface of the light control member LCM (refer to FIG. 2).

FIG. 10C is a sectional view (e.g., cross-sectional view) of the display module DM as viewed in the second direction DR2.

In FIG. 10C, the second light emitting element OL2 and the second light conversion layer WCP2 that correspond to the second emissive area PXA2 arranged or provided adjacent to the peripheral area NDA are illustrated.

Among the components illustrated in FIGS. 10A-10C, components that are substantially identical to the components described with reference to the drawings according to one or more embodiments may not be provided in the description or may be briefly described.

Referring to FIG. 10A, a first bank layer BK1a may include a first part PT1, a second part PT2, a third part PT3, a plurality of dummy bank layers DBK, and a plurality of sub-dummy bank layers SBK.

The first part PT1 may define the third opening OP3 that corresponds to the first emissive area PXA1. The second part PT2 may define the second opening OP2 that corresponds to the second emissive area PXA2. The third part PT3 may define the first opening OP1 that corresponds to the third emissive area PXA3. The first part PT1, the second part PT2, and the third part PT3 may be spaced and/or apart (e.g., spaced apart or separated) from one another.

Hereinafter, for convenience of description, one dummy bank layer DBK among the dummy bank layers DBK and one sub-dummy bank layer SBK among the sub-dummy bank layers SBK will be described.

The dummy bank layer DBK may be arranged or provided in the non-emissive area NPXA. The dummy bank layer DBK may be arranged or provided on the opposite sides of the second part PT2 that face away from each other in the first direction DR1. The dummy bank layer DBK may overlap the boundary between unit pixels PXU.

The dummy bank layer DBK may define a dummy opening D-OP. If (e.g., when) viewed from above the plane, the dummy opening D-OP may be arranged or provided on the opposite sides of the second emissive area PXA2 that face away from each other in the first direction DR1. The dummy opening D-OP may have an octagonal (e.g., substantially octagonal) shape in a plan view (when viewed from above a plane). However, the shape of the dummy opening D-OP is not limited thereto.

The sub-dummy bank layer SBK may connect the first part PT1, the second part PT2, the third part PT3, and the dummy bank layer DBK adjacent to one another. As the sub-dummy bank layer SBK connects the first part PT1, the second part PT2, the third part PT3, and the dummy bank layer DBK into one structure, the durability of the first bank layer BK1a may be improved or enhanced. The first part PT1, the second part PT2, the third part PT3, and the dummy bank layer DBK adjacent to one another and two sub-dummy bank layers SBK may define sub-dummy openings SW.

The sub-dummy openings SW may accommodate or provide the base resins BR1, BR2, and BR3 (refer to FIG. 7) that are incorrectly or unsuitably provided in the first to third openings OP1, OP2, and OP3. In one or more embodiments, defects in the display device DD (refer to FIG. 3) may be suppressed (or a degree or occurrence of defects in the display device DD may be reduced).

Referring to FIGS. 10A and 10B, a first spacer CS1a may be arranged or provided in the non-emissive area NPXA. The first spacer CS1a may be arranged or provided in the dummy opening D-OP defined by the dummy bank layer BDK. In the dummy opening D-OP, the first spacer CS1a may be arranged or provided on the lower surface of the first capping layer CP1 that is opposite to (or faces) the display panel DP.

The lower surface of the first spacer CS1a may protrude toward the display panel DP. The lower surface of the first spacer CS1a may be closer to the display panel DP than the lower surface of the dummy bank layer DBK. The height of the lower surface of the first spacer CS1a may be lower than the height of the lower surface of the dummy bank layer DBK.

The first spacer CS1a may include substantially the same material as the light transmitting layer LCP illustrated in FIG. 7. The first spacer CS1a may include a first base resin BR1 and scatterers SR dispersed or provided in the first base resin BR1. The first spacer CS1a may be concurrently (e.g., simultaneously) provided with the light transmitting layer LCP (refer to FIG. 7).

As illustrated in FIG. 10B, the second capping layer CP2 may cover the dummy bank layer DBK, the third part PT3, and the first spacer CS1a. In one or more embodiments, the second capping layer CP2 may cover the first part PT1, the second part PT2, and the sub-dummy bank layer SBK.

Referring to FIG. 10C, a second bank layer BK2a may be arranged or provided in the peripheral area NDA. The second bank layer BK2a may be arranged or provided on the lower surface of the first capping layer CP1 that is opposite to (or faces) the display panel DP. Although a plurality of second bank layers BK2a are illustrated in FIG. 10C, the plurality of second bank layers BK2a may be substantially integrally provided.

The thickness of the second bank layer BK2a may be greater than the thickness of the first bank layer BK1a. The lower surface of the second bank layer BK2a may be closer to the lower substrate SUB1 than the lower surface of the first bank layer BK1a.

Each of a plurality of second spacers CS2a may be arranged or provided in a corresponding dummy opening D-OP among the plurality of dummy openings D-OP defined by the second bank layer BK2a. The second spacer CS2a may have a smaller thickness than the first spacer CS1a. The height of the lower surface of the second spacer CS2a may be higher than the height of the lower surface of the first spacer CS1a. The lower surface of the second spacer CS2a may be further spaced and/or apart (e.g., further spaced apart or further separated) from the upper surface of the lower substrate SUB1 relative to the lower surface of the first spacer CS1a. The curvature of the outer surface of the first spacer CS1a may be greater than the curvature of the outer surface of the second spacer CS2a.

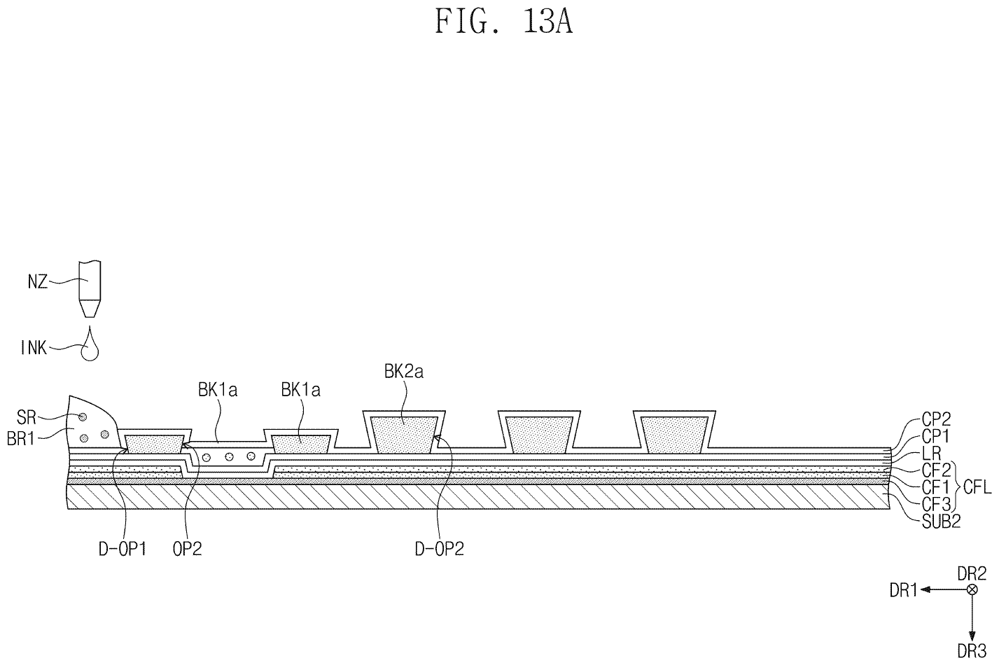

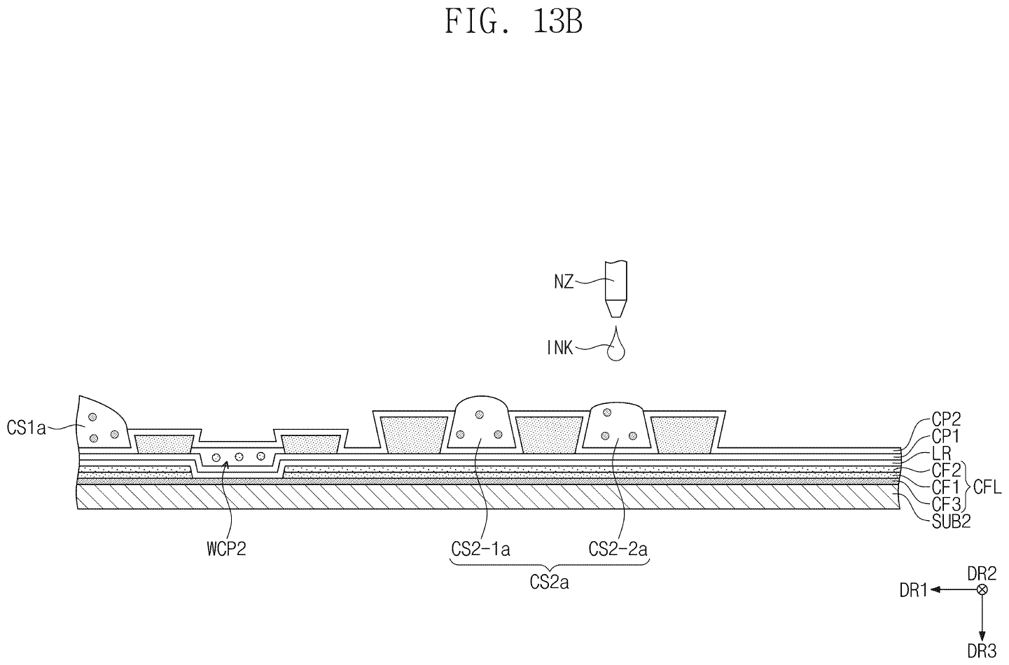

The thickness of the first spacer CS1a and the thicknesses of the plurality of second spacers CS2a may be adjusted by the amount of an ink INK (refer to FIG. 13B). More detailed description thereabout will be provided.

Because the thicknesses of the plurality of second spacers CS2a are smaller than the thickness of the first spacer CS1a, the thickness difference between the first bank BK1a and the second bank layer BK2a may be compensated for. In one or more embodiments, the encapsulation layer TFE arranged or provided in the peripheral area NDA may protrude upward, and thus the encapsulation layer TFE and the plurality of second spacers CS2a may be prevented from making contact with each other.

The plurality of second spacers CS2a may include a second-first spacer CS2-1a and a second-second spacer CS2-2a. The second-first spacer CS2-1a may be closer to the display area DA than the second-second spacer CS2-2a. The thickness of the second-first spacer CS2-1a may be greater than the thickness of the second-second spacer CS2-2a.

According to one or more embodiments of the present disclosure, the plurality of second spacers CS2a may have decreasing thicknesses as the plurality of second spacers CS2a are located farther away from the display area DA. For example, the thickness of the second-second spacer CS2-2a may be smaller than the thickness of the second-first spacer CS2-1a. As the thickness of the second-second spacer CS2-2a is decreased, the gap between the second-second spacer CS2-2a and the encapsulation layer TFE may be increased. In one or more embodiments, if (e.g., when) the display panel DP and the light control member LCM are bonded to each other, the second-second spacer CS2-2a may not be brought into contact with the encapsulation layer TFE and thus may not be damaged.

The second capping layer CP2 may cover the first bank layer BK1a, the second bank layer BK2a, the first spacer CS1a, and the plurality of second spacers CS2a. The sealing member SAL may be arranged or provided on the lower surface of the second capping layer CP2 that is opposite to (or faces) the display panel DP.

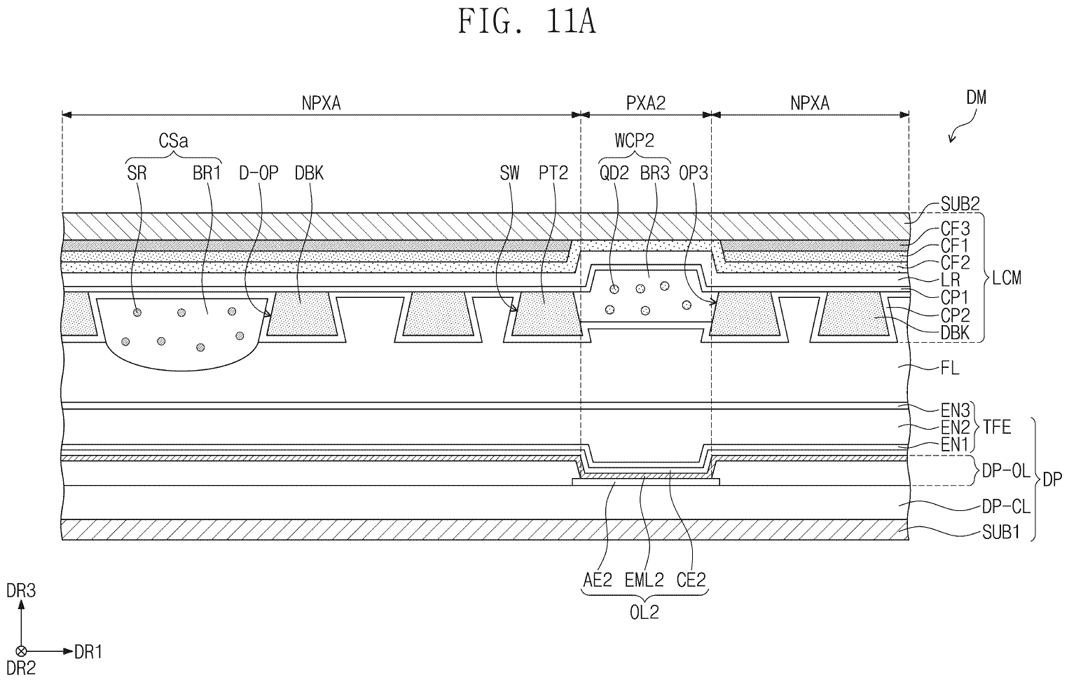

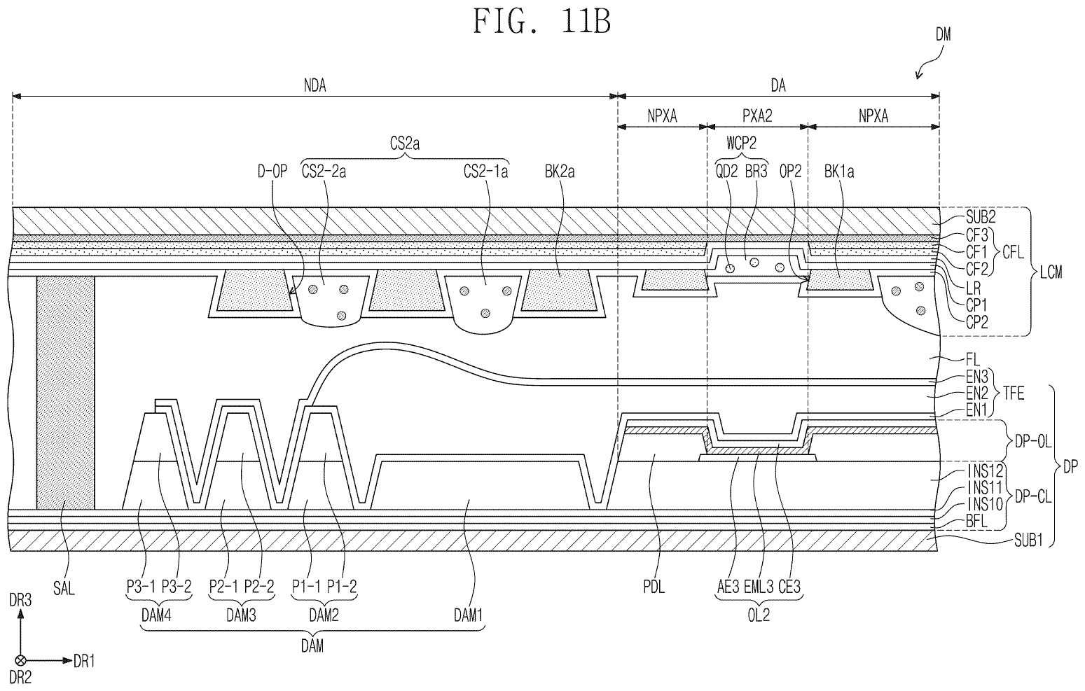

FIG. 11A is a sectional view (e.g., cross-sectional view) of the display module according to one or more embodiments of the present disclosure. FIG. 11B is a sectional view (e.g., cross-sectional view) of the display module according to one or more embodiments of the present disclosure.

FIG. 11A is a sectional view (e.g., cross-sectional view) of a portion that corresponds to the display area DA, and FIG. 11B is a sectional view (e.g., cross-sectional view) of a portion that corresponds to the peripheral area NDA adjacent to the display area DA.

Among the components illustrated in FIGS. 11A and 11B, components that are substantially identical to the components described with reference to the drawings according to one or more embodiments may not be provided in the description or may be briefly described.

The first bank layer BK1a may be arranged or provided on the lower surface of the first capping layer CP1. The second bank layer BK2a may be arranged or provided on the lower surface of the first capping layer CP1. The second capping layer CP2 may cover the first bank layer BK1a, the second bank layer BK2a, and the lower surface of the first capping layer CP1.

In the display area DA, the second capping layer CP2 may be arranged or provided in the dummy opening D-OP defined by the first bank layer BK1a. In the peripheral area NDA, the second capping layer CP2 may be arranged or provided in the plurality of dummy openings D-OP defined by the second bank layer BK2a.

The first spacer CS1a may be arranged or provided in the dummy opening D-OP defined by the first bank layer BK1a. The first spacer CS1a may be arranged or provided on the lower surface of the second capping layer CP2.

The plurality of second spacers CS2a may be arranged or provided in the dummy opening D-OP defined by the second bank layer BK2a. The plurality of second spacers CS2a may be arranged or provided on the lower surface of the second capping layer CP2.

FIGS. 12A-12D are views to illustrate a method of manufacturing the light control member illustrated in FIG. 8.

For convenience of description, the rear surface of the upper substrate SUB2 illustrated in FIG. 8 is illustrated as being arranged or provided over the front surface of the upper substrate SUB2.

FIGS. 12A-12D are sectional views (e.g., cross-sectional views), as viewed in the second direction DR2.

Among the components illustrated in FIGS. 12A-12D, components that are substantially identical to the components described with reference to the drawings according to one or more embodiments may not be provided in the description or may be briefly described.

Referring to FIG. 12A, the color filter layer CFL may be arranged or provided on the rear surface of the upper substrate SUB2. The low refractive index layer LR may be arranged or provided on the color filter layer CFL. The first capping layer CP1 may be arranged or provided on the low refractive index layer LR. An opening OP may be defined by the first capping layer CP1.

A preliminary bank layer IBK may be applied or provided on the first capping layer CP1. The preliminary bank layer IBK may cover the first capping layer CP1. The preliminary bank layer BK may include a black pigment and a water-repellent material. A portion of the preliminary bank layer IBK adjacent to the opening OP may be recessed if (e.g., when) compared with a portion of the preliminary bank layer IBK spaced and/or apart (e.g., spaced apart or separated) from the opening OP.

Referring to FIGS. 12A and 12B, a photo mask to block light may be arranged or provided on the preliminary bank layer IBK. The photo mask may have a plurality of openings defined therein. The openings may overlap the first openings OP1.

In one or more embodiments, a light source may be arranged or provided over the photo mask. An exposure process may be performed by light emitted from the light source. The light may be applied to the preliminary bank layer IBK through the openings. The molecular composition or components of the preliminary bank layer IBK to which the light is applied may be changed.

In one or more embodiments, an etching process may be performed after the exposure process is performed. The etching process may be a chemical etching process and/or a physical etching process. The chemical etching process may be a process that utilizes a developing solution. The physical etching process may be a dry etching process and/or a wet etching process. In one or more embodiments, the bank layer BK may be provided.

The bank layer BK may include the first bank layer BK1 and the second bank layer BK2. Because the preliminary bank layer IBK adjacent to the opening OP is recessed as illustrated in FIG. 12A, the thickness of the first bank layer BK1 may be smaller than the thickness of the second bank layer BK2.

Referring to FIG. 12C, a nozzle NZ may be arranged or provided over the first bank layer BK1 and the second bank layer BK2. The nozzle NZ may discharge the ink INK into the first opening OP1 defined by the first bank layer BK1. The ink INK may include a composition that constitutes the light transmitting layer LCP. For example, the ink INK may include the first base resin BR1 and the scatterers SR.

Referring to FIGS. 12C and 12D, the nozzle NZ may discharge the ink INK onto the first bank layer BK1. The nozzle NZ may discharge the ink INK onto the second bank layer BK2. The outer surface of the ink INK discharged onto the first bank layer BK1 and the second bank layer BK2 may have a set or predetermined curvature.

The amount of the ink INK discharged onto the first bank layer BK1 may be greater than the amount of the ink INK discharged onto the second bank layer BK2. In one or more embodiments, as illustrated in FIG. 12D, the thickness of the first spacer CS1 may be greater than the thicknesses of the plurality of second spacers CS2.

After the first spacer CS1 and the plurality of second spacers CS2 are provided, the second capping layer CP2 may cover the first spacer CS1, the first bank layer BK1, the light transmitting layer LCP, the second bank layer BK2, and the plurality of second spacers CS2.

FIGS. 13A and 13B are views to illustrate a method of manufacturing the light control member illustrated in FIG. 11B.

For convenience of description, the rear surface of the upper substrate SUB2 illustrated in FIG. 11B is illustrated as being arranged or provided over the front surface of the upper substrate SUB2.

FIGS. 13A and 13B are sectional views (e.g., cross-sectional views), as viewed in the second direction DR2.

Among the components illustrated in FIGS. 13A and 13B, components that are substantially identical to the components described with reference to the drawings according to one or more embodiments may not be provided in the description or may be briefly described.

Referring to FIGS. 13A and 13B, the second opening OP2 and a first dummy opening D-OP1 may be defined by the first bank layer BK1a. Second dummy openings D-OP2 may be defined by the second bank layer BK2a. The second quantum dots QD2 and the third base resin BR3 may be discharged into the second opening OP2 to provide the second light conversion layer WCP2.

The second capping layer CP2 may be arranged or provided on the second light conversion layer WCP2, the first bank layer BK1a, the second bank layer BK2a, and the first capping layer CP1. The second capping layer CP2 may cover the lower surface of the second light conversion layer WCP2, the lower surface of the first bank layer BK1a, the lower surface of the second bank layer BK2a, and the lower surface of the first capping layer CP1.

A nozzle NOZ may be arranged or provided over the first bank layer BK1a and the second bank layer BK2a. The nozzle NOZ may discharge an ink INK into the first dummy opening D-OP1. The nozzle NOZ may discharge the ink INK onto the lower surface of the second capping layer CP2 arranged or provided in the first dummy opening D-OP1. The outer surface of the ink INK discharged into the first dummy opening D-OP1 may have a set or predetermined curvature. Hereinafter, the outer surface of the ink INK may be defined as a surface exposed to the outside from the first bank layer BK1a or the second bank layer BK2a.

The nozzle NOZ may discharge the ink INK into the second dummy openings D-OP2. The nozzle NOZ may discharge the ink INK onto the lower surface of the second capping layer CP2 arranged or provided in the second dummy openings D-OP2. The outer surface of the ink INK discharged into the second dummy opening D-OP2 may have a set or predetermined curvature.

The amount of the ink INK discharged into the first dummy opening D-OP1 may be greater than the amount of the ink INK discharged into the second dummy openings D-OP2. The ink INK discharged into the first dummy opening D-OP1 and the second dummy openings D-OP2 may be cured. The cured ink INK may be defined as the first spacer CS1a and the plurality of second spacers CS2a. Because the amount of the ink INK discharged into the first dummy opening D-OP1 is greater than the amount of the ink INK discharged into the second dummy openings D-OP2, as illustrated in FIG. 11B, the thickness of the first spacer CS1a may be greater than the thickness of the plurality of second spacers CS2a.

According to one or more embodiments of the present disclosure, the second spacer arranged or provided adjacent to the border of the display device may have a smaller thickness than the first spacer arranged or provided in the display area of the display device. In one or more embodiments, if (e.g., when) the display panel and the light control member are bonded to each other, the second spacer may not be brought into contact with the display panel and thus may not be damaged. As a result, defects in the border of the display device may be reduced.

One or more embodiments of the present disclosure provide an electronic device including a power supply module configured or provided to supply power and the display device as described in one or more embodiments, wherein the display device is connected to the power supply module.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

A display device, an electronic device, a device for manufacturing substantially the same and/or any other relevant devices or components according to embodiments of the present invention described herein may be implemented utilizing any suitable hardware, firmware (e.g., an application-specific integrated circuit), software, or a combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

A person of ordinary skill in the art, in view of the present disclosure in its entirety, would appreciate that each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

While the present disclosure has been described with reference to one or more embodiments thereof, it will be apparent to those of ordinary skill in the art that one or more suitable changes and modifications may be made thereto without departing from the spirit and scope of the present disclosure as set forth in the following claims and equivalents thereof.

What is claimed is:

1. A display device, comprising:
a display panel comprising a display area and a peripheral area configured to be around the display area; and
a light control member provided on the display panel,
wherein the light control member comprises:
a light conversion layer configured to overlap the display area;
a light transmitting layer configured to overlap the display area and spaced from the light conversion layer;
a bank layer comprising a first bank layer provided between the light conversion layer and the light transmitting layer and a second bank layer configured to overlap the peripheral area; and
a plurality of spacers comprising a first spacer provided on a lower surface of the first bank layer configured to face the display panel and a second spacer provided on a lower surface of the second bank layer configured to face the display panel, and
wherein the first spacer and the second spacer have different thicknesses.

2. The display device as claimed in claim 1, wherein the first spacer has a greater thickness than the second spacer.

3. The display device as claimed in claim 2, wherein the second bank layer has a greater thickness than the first bank layer.

4. The display device as claimed in claim 3, wherein a lower surface of the first spacer configured to face the display panel has a lower height than a lower surface of the second spacer configured to face the display panel.

5. The display device as claimed in claim 2, wherein the display panel further comprises:
a lower substrate;
a circuit layer provided on the lower substrate;
a light emitting element layer provided on the circuit layer in the display area; and
an encapsulation layer configured to cover the light emitting element layer, and
wherein a portion of the encapsulation layer provided in the peripheral area protrudes further toward the light control member than a portion of the encapsulation layer provided in the display area.

6. The display device as claimed in claim 5, wherein the second spacer comprises a plurality of second spacers, and the plurality of second spacers have decreasing thicknesses as the plurality of second spacers are located farther away from the display area.

7. The display device as claimed in claim 1, wherein outer surfaces of the plurality of spacers have set curvatures.

8. The display device as claimed in claim 7, wherein an outer surface of the first spacer has a greater curvature than an outer surface of the second spacer.

9. The display device as claimed in claim 1, wherein the plurality of spacers comprise substantially the same material as the light transmitting layer.

10. A display device, comprising:
a display panel comprising a display area and a peripheral area configured to be around the display area in a plan view; and
a light control member provided on the display panel,
wherein the light control member comprises:
an upper substrate;
a bank layer provided between the upper substrate and the display panel and configured to define a first opening, a second opening, a third opening, and a plurality of dummy openings spaced from one another;
a light transmitting layer provided in the first opening;
light conversion layers provided in the second opening and the third opening; and
a plurality of spacers comprising a first spacer provided in the plurality of dummy openings and configured to overlap the display area and a second spacer provided in the plurality of dummy openings and configured to overlap the peripheral area, and
wherein the first spacer has a greater thickness than the second spacer.

11. The display device as claimed in claim 10, wherein a lower surface of the first spacer configured to face the display panel has a lower height than a lower surface of the second spacer configured to face the display panel.

12. The display device as claimed in claim 11, wherein the second spacer comprises:
a second-first spacer adjacent to a boundary between the display area and the peripheral area; and
a second-second spacer provided outward of the second-first spacer, and
wherein the second-first spacer has a greater thickness than the second-second spacer.

13. The display device as claimed in claim 12, wherein the display panel comprises:
a lower substrate;
a circuit layer provided on the lower substrate;
a light emitting element layer provided on the circuit layer in the display area; and
an encapsulation layer configured to cover the light emitting element layer, and
wherein a portion of the encapsulation layer configured to overlap the second spacer protrudes further upward than a portion of the encapsulation layer configured to overlap the first spacer.

14. The display device as claimed in claim 11, wherein the bank layer configured to overlap the display area is defined as a first bank layer, the bank layer configured to overlap the peripheral area is defined as a second bank layer, and the second bank layer has a greater thickness than the first bank layer.

15. The display device as claimed in claim 10, wherein the light control member further comprises a capping layer provided between the upper substrate and the display panel, and
wherein the capping layer covers lower surfaces of the plurality of spacers configured to face the display panel.

16. The display device as claimed in claim 10, wherein the light control member further comprises a capping layer provided between the upper substrate and the display panel and configured to cover the bank layer, the light transmitting layer, and the light conversion layers, and
wherein the capping layer is provided in the plurality of dummy openings, and the plurality of spacers are provided on a lower surface of the capping layer configured to face the display panel.

17. The display device as claimed in claim 10, wherein the plurality of spacers comprise substantially the same material as the light transmitting layer.

18. The display device as claimed in claim 10, wherein lower surfaces of the plurality of spacers configured to face the display panel have set curvatures.

19. An electronic device, comprising;
a power supply module configured to supply power; and
a display device connected to the power supply module,
wherein the display device comprises:
a display panel comprising a display area and a peripheral area configured to be around the display area; and
a light control member provided on the display panel,
wherein the light control member comprises:
a light conversion layer configured to overlap the display area;
a light transmitting layer configured to overlap the display area and spaced from the light conversion layer;
a bank layer comprising a first bank layer provided between the light conversion layer and the light transmitting layer and a second bank layer configured to overlap the peripheral area; and
a plurality of spacers comprising a first spacer provided on a lower surface of the first bank layer configured to face the display panel and a second spacer provided on a lower surface of the second bank layer configured to face the display panel, and
wherein the first spacer and the second spacer have different thicknesses.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
